(19) United States
(12) Patent Application Publication
(10) Pub. No.: US 2021/0049067 A1
(43) Pub. Date: Feb. 18, 2021

(54) MEMORY DEVICE AND METHOD OF OPERATING THE SAME

(71) Applicant: SK hynix Inc., Gyeonggi-do (KR)

(72) Inventors: Won Jae CHOI, Gyeonggi-do (KR); Ki Chang GWON, Gyeonggi-do (KR)

(21) Appl. No.: 16/825,841

(22) Filed: Mar. 20, 2020

(30) Foreign Application Priority Data
Aug. 16, 2019 (KR) 10-2019-0100583

(51) Int. Cl. G06F 11/10; G11C 11/56; G11C 16/24; G11C 16/26; G11C 16/04

(52) U.S. Cl. CPC G06F 11/1076; G11C 11/5642; G11C 11/5671; G11C 2211/5642; G11C 16/26; G11C 16/0483; G11C 16/24

(57) ABSTRACT

The present technology relates to an electronic device. A memory device performing efficient soft decoding by reducing the number of data provided to a memory controller includes a memory cell array and a page buffer connected to the memory cell array through a bit line. The page buffer includes a plurality of latches and a read data operating component configured to generate a soft bit by logically operating soft data, which are data read from the memory cell array, and to provide the soft bit to a memory controller, in a second read operation performed when a first read operation has failed.

### CROSS-REFERENCE TO RELATED APPLICATION

The present application claims priority under 35 U.S.C. § 119(a) to Korean patent application number 10-2019-0100583, filed on Aug. 16, 2019, which is incorporated herein by reference in its entirety.

### BACKGROUND

### Field of Invention

The present disclosure relates to an electronic device, and more particularly, to a memory device and a method of operating the same.

### Description of Related Art

A storage device is a device for storing data under control of a host device such as a computer, a smart phone, or a smart pad. The storage device includes a device for storing data into a magnetic disk such as a hard disk drive (HDD), a device that stores data in a semiconductor memory such as a solid state drive (SSD), or a memory card, in particular, a non-volatile memory.

The storage device may include a memory device for storing data and a memory controller for storing data into the memory device. The memory device may be classified into a volatile memory and a non-volatile memory. Here, the non-volatile memory includes a read only memory (ROM), a programmable ROM (PROM), an electrically programmable ROM (EPROM), an electrically erasable and programmable ROM (EPM), a flash memory, a phase-change RAM (PRAM), a magnetic RAM (MRAM), a resistive RAM (RRAM), a ferroelectric RAM (FRAM) and the like.

### SUMMARY

An embodiment of the present disclosure provides a memory device and a method of operating the same capable of performing efficient soft decoding by reducing the number of data output to a memory controller.

A memory device according to an embodiment of the present disclosure may include a memory cell array and a page buffer connected to the memory cell array through a bit line. The page buffer may include a plurality of latches, and a read data operating component configured to generate a soft bit by operating soft data, which are data read from the memory cell array, and to provide the soft bit to a memory controller, in a second read operation performed when a first read operation has failed.

A method of operating a memory device according to an embodiment of the present disclosure is a method of operating a memory device comprising a memory cell array and a page buffer connected to the memory cell array through a bit line. The method may include performing a first read operation, changing a read voltage to perform a second read operation when the first read operation has failed, logically operating soft data which are data read from the memory cell array in the second read operation to generate at least one soft bit and providing the at least one soft bit to a memory controller.

A memory device according to an embodiment of the present disclosure may include a memory cell array and a page buffer connected to the memory cell array through a bit line. The page buffer may include a plurality of latches and a plurality of transistors, and wherein the page buffer outputs a soft bit generated by logically operating data provided to a second node connected to a latch included in the page buffer among the plurality of latches, according to data provided to a first node connected to the bit line.

A method of correcting error data transferring from a memory device to a memory controller, the method may include performing, by the memory controller, a first error correction for the error data, requesting, by the memory controller, the memory device for soft data, when the first error correction for the error data has failed, reading, by the memory device, the predetermined number of soft data, performing, by the memory device, a logic operation on the predetermined number of the soft data to generate soft bits less than the number of the soft data, wherein the soft bit indicates logically operated data, transferring the soft bits from the memory device to the memory controller and performing, by the memory controller, a second error correction on the soft bits.

According to the present technology, when an error correction operation for correcting an error included in read data is failed, a read operation corresponding to a soft read command is performed, and only a soft bit generated based on a result of performing the read operation is output to a memory controller. Therefore, soft decoding may be performed without outputting all read data.

These and other features and advantages of the present disclosure will become apparent to those skilled in the art of the invention from the following detailed description in conjunction with the following drawing.

### BRIEF DESCRIPTION OF THE DRAWINGS

FIG. 1 is a block diagram illustrating a storage device in accordance with some embodiments of the present disclosure.

FIG. 2 illustrates a structure of a memory device of FIG. 1 in accordance with some embodiments of the present disclosure.

FIG. 3 illustrates a memory block in accordance with some embodiments of the present disclosure.

FIG. 4 illustrates a process of outputting a soft read command in accordance with some embodiments of the present disclosure.

FIGS. 5A, 5B, and 5C illustrate an operation of the memory device corresponding to the soft read command in accordance with some embodiments of the present disclosure.

FIGS. 6A and 6B illustrate a method of generating a soft bit in accordance with some embodiments of the present disclosure.

FIG. 7 illustrates a method of generating the soft bit in accordance with some embodiments of the present disclosure.

FIGS. 8A and 8B illustrate an operation of the memory device corresponding to the soft read command in accordance with some embodiments of the present disclosure.

FIGS. 9A and 9B illustrate the soft bit generated according to the operation of the memory device of FIG. 8 in accordance with some embodiments of the present disclosure.

FIGS. 10A and 10B illustrate another soft bit generated by the operation of the memory device of FIGS. 8A and 8B in accordance with some embodiments of the present disclosure.

FIGS. 11A and 11B illustrate an operation of the memory device corresponding to the soft read command in accordance with some embodiments of the present disclosure.

FIGS. 12A and 12B illustrate the soft bit generated according to the operation of the memory device of FIG. 11 in accordance with some embodiments of the present disclosure.

FIGS. 13A and 13B illustrate another soft bit generated by the operation of the memory device of FIGS. 11A and 11B in accordance with some embodiments of the present disclosure.

FIGS. 14A and 14B illustrate another soft bit generated by the operation of the memory device of FIGS. 11A and 11B in accordance with some embodiments of the present disclosure.

FIGS. 15A and 15B illustrate the soft bit output according to the operation of the memory device of FIG. 11 in accordance with some embodiments of the present disclosure.

FIG. 16 illustrates the operation of the memory device in accordance with some embodiments of the present disclosure.

FIG. 17 illustrates the operation of the memory device in accordance with some embodiments of the present disclosure.

FIG. 18 illustrates the operation of the memory device in accordance with some embodiments of the present disclosure.

FIG. 19 illustrates the operation of the memory device in accordance with some embodiments of the present disclosure.

FIG. 20 is a block diagram illustrating a memory card system including the storage device in accordance with some embodiments of the present disclosure.

FIG. 21 is a block diagram illustrating a solid state drive (SSD) system including the storage device in accordance with some embodiments of the present disclosure.

### DETAILED DESCRIPTION

Specific structural or functional descriptions of embodiments according to the concept which are disclosed in the present specification or application are illustrated only to describe the embodiments according to the concept of the present disclosure. The embodiments according to the concept of the present disclosure may be carried out in various forms and the descriptions are not limited to the embodiments described in the present specification or application.

Hereinafter, an embodiment of the present disclosure will be described with reference to the accompanying drawings so that those skilled in the art may easily implement the technical spirit of the present disclosure.

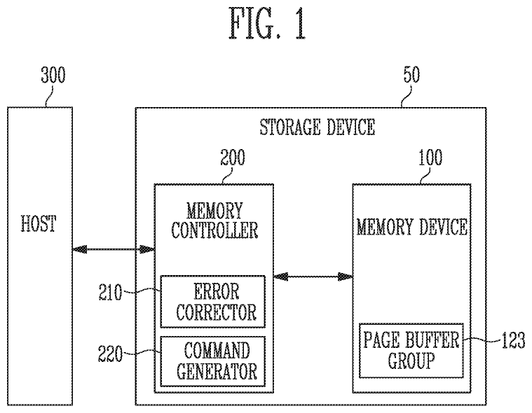

FIG. 1 is a block diagram illustrating a storage device in accordance with some embodiments of the present disclosure.

Referring to FIG. 1, the storage device 50 may include a memory device 100 and a memory controller 200.

The storage device 50 may store data under control of a host 300 such as a cellular phone, a smartphone, an MP3 player, a laptop computer, a desktop computer, a game player, a TV, a tablet PC, or an in-vehicle infotainment system.

The storage device 50 may be manufactured as one of various types of storage devices according to a host interface for communicating with the host 300. For example, the storage device 50 may be configured as any one of various types of storage devices including a multimedia card such as a SSD, an MMC, an eMMC, an RS-MMC and a micro-MMC, a secure digital card such as a SD, a mini-SD and a micro-SD, a universal serial bus (USB) storage device, a universal flash storage (UFS) device, a storage device such as a personal computer memory card international association (PCMCIA) card, a storage device such as a peripheral component interconnection (PCI) card, a storage device such as a PCI express (PCI-E) card, a compact flash (CF) card, a smart media card, and a memory stick.

The storage device 50 may be manufactured as any one of various types of packages. For example, the storage device 50 may be manufactured as any one of various types of package types, such as a package on package (POP), a system in package (SIP), a system on chip (SOC), a multi-chip package (MCP), a chip on board (COB), a wafer-level fabricated package (WFP), and a wafer-level stack package (WSP).

The memory device 100 may store data. The memory device 100 may operate in response to control of the memory controller 200. The memory device 100 may include a memory cell array including a plurality of memory cells for storing the data. The memory cell array may include a plurality of memory blocks. Each of the memory blocks may include a plurality of memory cells, and the plurality of memory cells may form a plurality of pages. In an embodiment, the page may indicate a basic unit for storing data in the memory device 100 or reading data stored in the memory device 100. The memory block may be a basic unit for erasing data.

The memory device 100 may include a page buffer group 123 including a plurality of page buffers. Each of the plurality of page buffers may be connected to the memory cell array through a bit line. In an embodiment of the present disclosure, when data stored in the memory cell array is transmitted to the page buffer through each bit line during a read operation, the page buffer may temporarily store the transmitted data.

In an embodiment of the present disclosure, when a correction of an error included in read data received from the memory device 100 is failed, the memory device 100 may receive a soft read command from the memory controller 200 and may perform a read operation using a read voltage level different from a previous read voltage. When a result of performing the read operation using the different read voltage is output to the memory controller 200, the memory controller 200 may perform an error correction operation of correcting the error of the read data again.

In an embodiment of the present disclosure, the memory device 100 may perform the read operation with the different read voltage level in response to the soft read command received from the memory controller 200 to output data generated on the basis of the read operation to the memory controller 200.

For example, after setting initial data, the memory device 100 may change the initial data according the read data to output the changed data to the memory controller 200. Alternatively, the memory device 100 may generate new data obtained by performing a specific operation (for example, an exclusive-NOR operation) on the read data to output the new data to the memory controller 200.

Therefore, in some embodiments of the present disclosure, since the memory device 100 outputs only the changed data or the new data without needing to output all read data, the number of data output from the memory device 100 to the memory controller 200 may be reduced. Thus, as the number of data provided to the memory controller 200 is reduced, the memory controller 200 may efficiently perform an operation of correcting an error.

In an embodiment of the present disclosure, the memory device 100 may be a double data rate synchronous dynamic random access memory (DDR SDRAM), a low power double data rate4 (LPDDR4) SDRAM, a graphics double data rate (GDDR) SDRAM, a low power DDR (LPDDR), a Rambus dynamic random access memory (RDRAM), a NAND flash memory, a vertical NAND flash memory, a NOR flash memory device, a resistive random access memory (RRAM), a phase-change memory (PRAM), a magnetoresistive random access memory (MRAM), a ferroelectric random access memory (FRAM), a spin transfer torque random access memory (STT-RAM), or the like. Herein, for convenience of description, it is assumed that the memory device 100 is a NAND flash memory.

The memory device 100 may be implemented as a two-dimensional array structure or a three-dimensional array structure. Hereinafter, the three-dimensional array structure is described as an example, but the present disclosure is not limited to the three-dimensional array structure. The present disclosure may be applicable not only to a flash memory device in which a charge storage layer consists of a conductive floating gate (FG), but also to a charge trap flash (CTF) in which the charge storage layer consists of an insulating film.

In an embodiment of the present disclosure, the memory device 100 may operate in the same way as a single level cell (SLC) in which one data bit is stored into one memory cell. Alternatively, the memory device 100 may operate in a manner that stores at least two data bits into one memory cell. For example, the memory device 100 may operate in the same way as a multi-level cell (MLC) of storing two data bits into one memory cell, a triple level cell (TLC) of storing three data bits into one memory cell, or a quadruple level cell (QLC) of storing four data bits into one memory cell.

The memory device 100 may be configured to receive a command and an address from the memory controller 200 and access a region selected by the address in the memory cell array. That is, the memory device 100 may perform an operation corresponding to the command on the region selected by the address. For example, the memory device 100 may perform a write operation (program operation), a read operation, or an erase operation according to the received command. For example, when a program command is received, the memory device 100 may program data into the region selected by the address. When a read command is received, the memory device 100 may read data from the region selected by the address. When an erase command is received, the memory device 100 may erase data stored in the region selected by the address.

The memory controller 200 may include an error corrector 210. The error corrector 210 may correct an error of the read data received from the memory device 100. Specifically, the error corrector 210 may correct an error of data in which error correction is failed, using a log-likelihood ratio (LLR) or a likelihood ratio (LR) generated based on an error correction code (for example, a Bose-Chaudhuri-Hocquenghem code (BCH code), a low-density parity-check Code, or the like) or read data received from the memory device 100. In an embodiment of the present disclosure, the greater an absolute value of the log-likelihood ratio (LLR) or the likelihood ratio (LR), the higher reliability of the read data.

In an embodiment of the present disclosure, when the error correction of the read data is failed in spite of the error correction operation of the error corrector 210, the error corrector 210 may generate error information. The error information may be provided to a command generator 220.

The memory controller 200 may include the command generator 220. The command generator 220 may generate a command corresponding to a request received from the host 300 or a command corresponding to an internal operation of the memory controller 200. When the memory device 100 receives the command from the command generator 220, the memory device 100 may perform an operation corresponding to the command.

For example, the command generator 220 may generate a soft read command based on the error information received from the error corrector 210 and output the soft read command to the memory device 100. The soft read command may be a command for instructing to perform the read operations a plurality of times using a voltage higher than a previously used read voltage and a voltage lower than the previously used read voltage. For example, if the previously used read voltage is 1V, the voltage higher than a previously used read voltage may be 1.2V and the voltage lower than the previously used read voltage may be 0.8V. That is, the next read operations may be performed based on voltages that are at a predetermined distance from the previously used read voltage.

The memory device 100 may perform the read operations a plurality of times based on the soft read command, and transmit results of the read operations to the memory controller 200.

However, in some embodiments of the present disclosure, the memory device 100 may not provide all data acquired from the plurality of read operations performed according to the soft read command to the memory controller 200. The memory device 100 may perform a logical operation on all read data acquired from the plurality of read operations to provide the result of the logical operation to the memory controller 200. Since the memory device 100 provides only the result of the logical operation to the memory controller 220, rather than all data acquired from the plurality read operations, the number of data provided from the memory device 100 to memory controller 200 may be reduced, allowing an increase of efficiency of the error correction operation of the error corrector 210.

The memory controller 200 may control overall operations of the storage device 50.

When a power voltage is supplied to the storage device 50, the memory controller 200 may execute firmware FW. When the memory device 100 is configured as a flash memory device 100, the memory controller 200 may operate firmware such as a flash translation layer (FTL) for controlling communication between the host 300 and the memory device 100.

In an embodiment, the memory controller 200 may receive data and a logical block address (LBA) from the host 300 and convert the LBA into a physical block address (PBA) indicating an address of memory cells in which data included in the memory device 100 is to be stored. In addition, the memory controller 200 may store a logical-physical address mapping table for mapping the LBA and the PBA in a buffer memory.

The memory controller 200 may control the memory device 100 to perform the program operation, the read operation, the erase operation, or the like according to the request of the host 300. For example, when a program request is received from the host 300, the memory controller 200 may converts the program request into a program command, and may provide the program command, the PBA, and data to the memory device 100. When a read request is received from the host 300 together with the LBA, the memory controller 200 may change the read request into a read command, select a PBA corresponding to the LBA, and then provide the read command and the PBA to the memory device 100. When an erase request is received from the host 300 together with the LBA, the memory controller 200 may change the erase request into an erase command, select a PBA corresponding to the LBA, and then provide the erase command and the PBA to the memory device 100.

In an embodiment of the present disclosure, the memory controller 200 may generate and transmit the program command, the address, and the data to the memory device 100 even without the request from the host 300. For example, the memory controller 200 may provide a command, an address, and data to the memory device 100 so as to perform background operations such as a program operation for wear leveling and a program operation for garbage collection.

In an embodiment of the present disclosure, the storage device 50 may further include a buffer memory (not shown). The memory controller 200 may control data exchange between the host 300 and the buffer memory. Alternatively, the memory controller 200 may temporarily store system data for controlling the memory device 100 into the buffer memory. For example, the memory controller 200 may temporarily store data input from the host 300 into the buffer memory, and then transmit data temporarily stored in the buffer memory to the memory device 100.

In various embodiments, the buffer memory may be used as an operation memory and a cache memory of the memory controller 200. The buffer memory may store codes or commands executed by the memory controller 200. Alternatively, the buffer memory may store data from the memory controller 200.

In an embodiment of the present disclosure, the buffer memory may be implemented as a dynamic random access memory (DRAM) such as a double data rate synchronous dynamic random access memory (DDR SDRAM), a DDR4 SDRAM, a low power double data rate4 (LPDDR4) SDRAM, a graphics double data rate (GDDR) SDRAM, a low power DDR (LPDDR), or Rambus dynamic random access memory (DRAM), or a static random access memory (SRAM).

In various embodiments of the present disclosure, the buffer memory may be connected from an outside of the storage device 50. In this case, the volatile memory devices 100 connected to the outside of the storage device 50 may serve as the buffer memory.

In an embodiment of the present disclosure, the memory controller 200 may control at least two or more memory devices 100. In this case, the memory controller 200 may control the memory devices 100 according to an interleaving scheme in order to improve operation performance.

The host 300 may communicate with the storage device 50 using at least one of various communication methods such as a universal serial bus (USB), a serial AT attachment (SATA), a serial attached SCSI (SAS), a high speed interchip (HSIC), a small computer system Interface (SCSI), a peripheral component interconnection (PCI), a PCI express (PCIe), a nonvolatile memory express (NVMe), a universal flash storage (UFS), a secure digital (SD), a multi-media card (MMC), an embedded MMC (eMMC), a dual in-line memory module (DIMM), a registered DIMM (RDIMM), and a load reduced DIMM (LRDIMM).

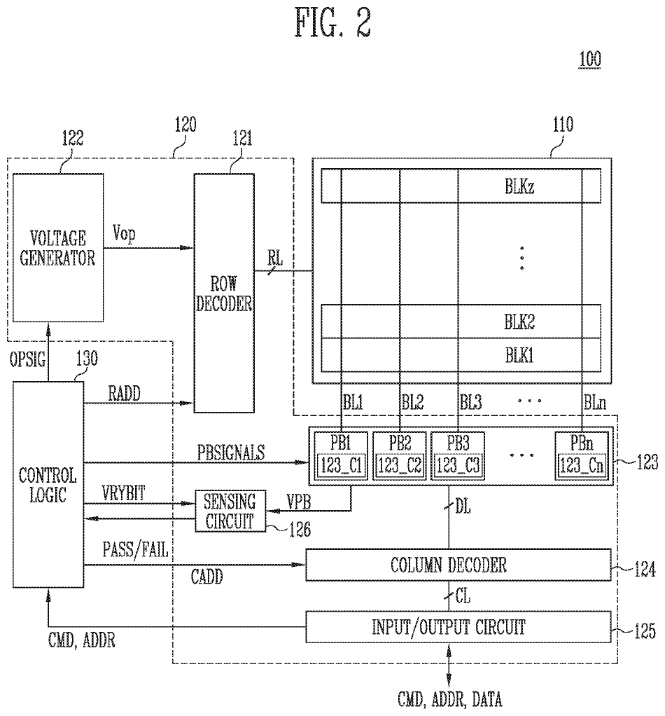

FIG. 2 is diagram illustrating a structure of the memory device of FIG. 1 in accordance with some embodiments of the present disclosure.

Referring to FIG. 2, the memory device 100 may include a memory cell array 110, a peripheral circuit 120, and a control logic 130.

The memory cell array 110 includes a plurality of memory blocks BLK1 to BLKz. The plurality of memory blocks BLK1 to BLKz may be connected to a row decoder 121 through row lines RL. The plurality of memory blocks BLK1 to BLKz may be connected to the page buffer group 123 through bit lines BL1 to BLn. Each of the plurality of memory blocks BLK1 to BLKz includes a plurality of memory cells. In accordance with an embodiment of the present disclosure, the plurality of memory cells may be configured as non-volatile memory cells. Memory cells connected to the same word line may be defined as one page. Therefore, one memory block may include a plurality of pages.

The row lines RL may include at least one source select line, a plurality of word lines, and at least one drain select line.

Each of the memory cells included in the memory cell array 110 may be configured as a single level cell (SLC) that stores one data bit, a multi-level cell (MLC) that stores two data bits, a triple level cell (TLC) that stores three data bits, or a quadruple level cell (QLC) that stores four data bits.

The peripheral circuit 120 may be configured to perform the program operation, the read operation, or the erase operation on a selected region of the memory cell array 110 under control of the control logic 130. The peripheral circuit 120 may drive the memory cell array 110. For example, the peripheral circuit 120 may apply various operation voltages to the row lines RL and the bit lines BL1 to BLn or discharge the applied voltages under the control of the control logic 130.

The peripheral circuit 120 may include a row decoder 121, a voltage generator 122, the page buffer group 123, a column decoder 124, an input/output circuit 125, and a sensing circuit 126.

The row decoder 121 may be connected to the memory cell array 110 via the row lines RL. The row lines RL may include at least one source select line, a plurality of word lines, and at least one drain select line. In an embodiment of the present disclosure, the word lines may include normal word lines and dummy word lines. In an embodiment of the present disclosure, the row lines RL may further include a pipe select line.

The row decoder 121 may be configured to decode a row address RADD received from the control logic 130. The row decoder 121 may select at least one memory block among the memory blocks BLK1 to BLKz according to a decoded address. In addition, the row decoder 121 may select at least one word line of the memory block selected to apply the voltages generated by the voltage generator 122 to at least one word line WL according to the decoded address.

For example, during the program operation, the row decoder 121 may apply a program voltage to a selected word line and apply a program pass voltage of a level lower than the program voltage to an unselected word line. During the program verification operation, the row decoder 121 may apply a verification voltage to the selected word line and a verification pass voltage higher than the verification voltage to the unselected word line. During the read operation, the row decoder 121 may apply a read voltage to the selected word line and apply a read pass voltage higher than the read voltage to the unselected word line.

In an embodiment of the present disclosure, the erase operation of the memory device 100 may be performed for each memory block. During the erase operation, the row decoder 121 may select one memory block according to the decoded address. During the erase operation, the row decoder 121 may apply a ground voltage to the word lines connected to the selected memory block.

The voltage generator 122 may operate under the control of the control logic 130. The voltage generator 122 may be configured to generate a plurality of voltages using an external power voltage supplied to the memory device 100. Specifically, the voltage generator 122 may generate various operation voltages Vop used for the program, read, and erase operations, in response to operation signal OPSIG. For example, the voltage generator 122 may generate the program voltage, the verification voltage, the pass voltage, the read voltage, the erase voltage, and the like in response to the control of the control logic 130.

In accordance with some embodiments of the present disclosure, the voltage generator 122 may generate an internal power voltage by regulating the external power voltage. The internal power voltage generated by the voltage generator 122 may be used as an operation voltage of the memory device 100.

In accordance with some embodiments of the present disclosure, the voltage generator 122 may generate a plurality of voltages using the external power voltage or the internal power voltage.

For example, the voltage generator 122 may include a plurality of pumping capacitors that receive the internal power voltage, and may selectively activate the plurality of pumping capacitors to generate the plurality of voltages, in response to the control of the control logic 130.

The generated plurality of voltages may be supplied to the memory cell array 110 by the row decoder 121.

The page buffer group 123 may include first to n-th page buffers PB1 to PBn. The first to n-th page buffers PB1 to PBn may be connected to the memory cell array 110 through the first to n-th bit lines BL1 to BLn, respectively. The first to n-th page buffers PB1 to PBn may operate under the control of the control logic 130. Specifically, the first to n-th page buffers PB1 to PBn may operate in response to a page buffer control signals PBSIGNALS. For example, the first to n-th page buffers PB1 to PBn may temporarily store data received through the first to n-th bit lines BL1 to BLn, or may sense a voltage or a current of the bit lines BL1 to BLn during the read or verification operation.

Specifically, during the program operation, when the program voltage is applied to the selected word line, the first to n-th page buffers PB1 to PBn may transfer data DATA received from the input/output circuit 125 to the selected memory cell through the first to n-th bit lines BL1 to BLn. The memory cells of the selected page may be programmed according to the transferred data DATA. During the program verification operation, the first to n-th page buffers PB1 to PBn may read page data by sensing the voltage or the current received from the selected memory cells through the first to n-th bit lines BL1 to BLn.

During the read operation, the first to n-th page buffers PB1 to PBn may read the data DATA from the memory cells of the selected page through the first to n-th bit lines BL1 to BLn, and may output the read data DATA to the input/output circuit 125 under the control of the column decoder 124.

During the erase operation, the first to n-th page buffers PB1 to PBn may float the first to n-th bit lines BL1 to BLn or apply the erase voltage.

In an embodiment of the present disclosure, the first to n-th page buffers PB1 to PBn may include first to n-th read data operating components 123_C1 to 123_Cn, respectively. The first to n-th read data operating components 123_C1 to 123_Cn may perform exclusive-NOR (XNOR) operation on read data temporarily stored in latches of the first to n-th page buffers PB1 to PBn, respectively, and may output a soft bit, which indicates logically operated data, to the column decoder 124. The XNOR operation may be a match check operation to check whether input values match each other.

In accordance with the some embodiments of the present disclosure, since the first to n-th page buffers PB1 to PBn perform the XNOR operation on the read data from the memory cells to provide logically operated (logical NXOR) data to memory controller 200, the number of data provided from the memory device 100 to the memory controller 200 of FIG. 1 may be reduced. In addition, as the number of the data provided to the memory controller 200 of FIG. 1 is reduced, some procedures involved in the error correction operation of the memory controller 200 of FIG. 1 may be omitted. Therefore, the error correction efficiency of the memory controller 200 of FIG. 1 may be increased.

The column decoder 124 may transfer data between the input/output circuit 125 and the page buffer group 123 in response to a column address CADD. For example, the column decoder 124 may exchange data with the first to n-th page buffers PB1 to PBn through data lines DL, or may exchange data with the input/output circuit 125 through column lines CL.

The input/output circuit 125 may transfer the command CMD and the address ADDR received from the memory controller 200 of FIG. 1 described with reference to FIG. 1 to the control logic 130, or may exchange data DATA with the column decoder 124.

The sensing circuit 126 may generate a reference current in response to a permission bit signal VRYBIT during the read operation or the verification operation, and compare a sensing voltage VPB received from the page buffer group 123 with a reference voltage generated by the reference current to output a pass signal PASS or a fail signal FAIL.

The control logic 130 may output the operation signal OPSIG, the row address RADD, the page buffer control signals PBSIGNALS, and the permission bit VRYBIT in response to the command CMD and the address ADDR to control the peripheral circuit 120. For example, the control logic 130 may control the read operation of the selected memory block in response to a sub block read command and the address. In addition, the control logic 130 may control the erase operation of the selected sub block of the selected memory block in response to the sub block erase command and the address. In addition, the control logic 130 may determine whether the verity operation has passed or failed in response to the pass or fail signal PASS or FAIL.

The memory cells of the memory cell array 110 may be programmed to any one of a plurality of program states according to data stored in each memory cell. A target program state of the memory cell may be determined as any one of the plurality of program states according to the data to be stored.

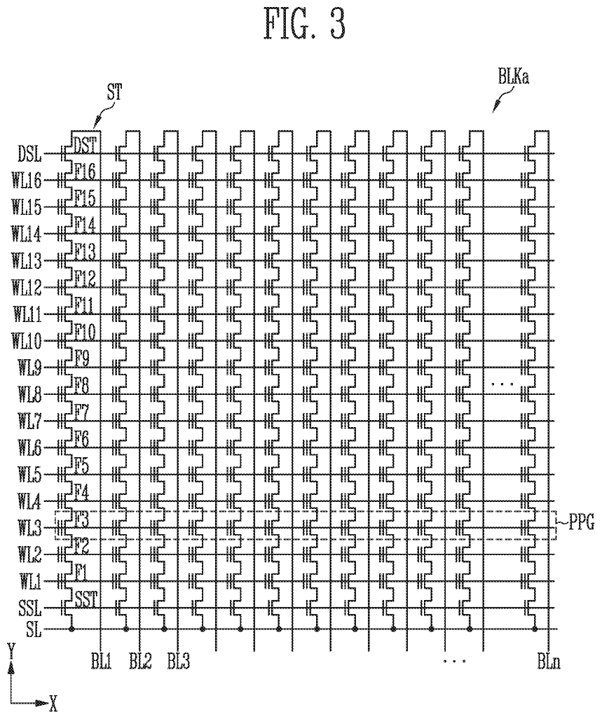

FIG. 3 is a diagram Illustrating the memory block in accordance with some embodiments of the present disclosure.

Referring to FIGS. 2 and 3, FIG. 3 is a circuit diagram illustrating any one memory block BLKa among the plurality of memory blocks BLK1 to BLKz of the memory cell array 110 of FIG. 2.

A first select line, word lines, and a second select line arranged in parallel with each other may be connected to the memory block BLKa. For example, the word lines may be arranged in parallel with each other between the first and second select lines. Herein, the first select line may indicate the source select line SSL, and the second select line may indicate the drain select line DSL.

More specifically, the memory block BLKa may include a plurality of strings connected between the bit lines BL1 to BLn and a source line SL. The bit lines BL1 to BLn may be connected to the strings, respectively, and the source line SL may be commonly connected to the strings. Since the strings may be configured to be identical to each other, a string ST connected to the first bit line BL1 will be specifically described below, as an example.

The string ST may include a source select transistor SST, a plurality of memory cells F1 to F16, and a drain select transistor DST connected in series between the source line SL and the first bit line BL1. One string ST may include at least one or more of the source select transistor SST and the drain select transistor DST, and the number of the memory cells F1 to F16 may be more than the ones shown in the drawing.

A source of the source select transistor SST may be connected to the source line SL and a drain of the drain select transistor DST may be connected to the first bit line BL1. The memory cells F1 to F16 may be connected in series between the source select transistor SST and the drain select transistor DST. Gates of the source select transistors SST included in the different strings may be connected to the source select line SSL, gates of the drain select transistors DST may be connected to the drain select line DSL, and gates of the memory cells F1 to F16 may be connected to a plurality of word lines WL1 to WL16. A group of the memory cells connected to the same word line among the memory cells included in different strings may be referred to as a physical page PPG. Therefore, the memory block BLKa may include the physical pages PPG corresponding to the number of the word lines WL1 to WL16.

One memory cell may store one bit of data. This is commonly referred to as a single level cell (SLC). In this case, one physical page PPG may store one logical page (LPG) data. One logical page (LPG) data may include data bits corresponding to the number of memory cells included in one physical page PPG. In addition, one memory cell may store two or more bits of data. This is commonly referred to as a multi-level cell (MLC). In this case, one physical page PPG may store two or more logical page (LPG) data.

Conventionally, a memory cell in which two or more bits of data are stored in one memory cell is referred to as a multi-level cell (MLC). However, recently, as the number of bits of data stored in one memory cell increases, the multi-level cell (MLC) refers to a memory cell in which two bits of data is stored, a memory cell in which three or more bits of data are stored is referred to as a triple level cell (TLC), and a memory cell in which four or more bits of data are stored is referred to as a quadruple level cell (QLC). In addition, a memory cell for storing a plurality of bits of data has been developed, and the present embodiment may be applicable to a memory cell for storing two or more bits of data.

In another embodiment of the present disclosure, the memory block may have a three-dimensional structure. Each memory block may include a plurality of memory cells stacked on a substrate. Such plurality of memory cells may be arranged along a +X direction, a +Y direction, and a +Z direction.

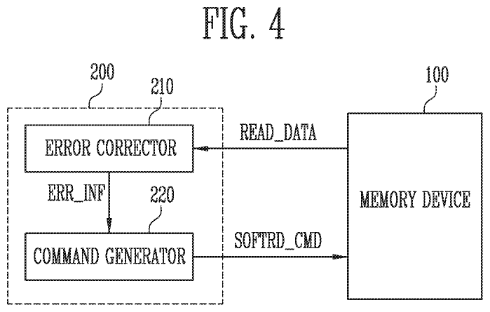

FIG. 4 is a diagram illustrating a process of outputting the soft read command in accordance with some embodiments of the present disclosure.

Referring to FIG. 4, the memory controller 200 of FIG. 4 may include the error corrector 210 and the command generator 220.

The error corrector 210 may receive read data READ_DATA read from the memory device 100. The read data READ_DATA may be acquired from an operation performed by the memory device 100 according to a read command (not shown).

An error may be included in the read data READ_DATA during a read process or due to deterioration by retention. Therefore, in order to correct the error included in the read data READ_DATA, the error corrector 210 may perform an error correction operation on the read data READ_DATA. For example, the error corrector 210 may correct an error of the read data READ_DATA by using a code such as a Bose-Chaudhuri-Hocquenghem code (BCH code) or a low-density parity-check code (LDPC).

However, when the error correction on the read data READ_DATA has failed despite the error correction operation, the error corrector 210 may output error information ERR_INF. The error information ERR_INF may indicate that the error correction has failed. The memory controller 200 may perform to correct the error of the read data READ_DATA based on the error information ERR_INF, as follows.

For example, the command generator 220 may receive the error information ERR_INF from the error corrector 210, and then generate the soft read command SOFTRD_CMD to output the soft read command SOFTRD_CMD to the memory device 100. The operation corresponding to the soft read command SOFTRD_CMD may indicate an operation for a second error correction when the error corrector 210 fails to correct the error of the read data READ_DATA during a first error correction.

Specifically, the memory device 100 may receive the soft read command SOFTRD_CMD from the command generator 220 to perform the read operation a plurality of times. At this time, voltages used to read the data for the second error correction may be higher or lower than the voltages used to read the data for the first error correction.

For example, when the memory device 100 performs the read operations twice according to the soft read command SOFTRD_CMD, the memory device 100 may perform the read operations with a voltage higher than the previously used read voltage (for example, the voltage used to read data for the first error correction), by qV and a voltage lower than the previously used read voltage by qV.

In addition, when the memory device 100 performs the read operations four times according to the soft read command SOFTRD_CMD, the memory device 100 may perform the read operations with a voltage higher than the previously used read voltage by 2*qV and a voltage lower than the previously used read voltage by 2*qV in addition to the voltages used when performing the read operations twice.

In addition, when the memory device 100 performs the read operations six times according to the soft read command SOFTRD_CMD, the memory device 100 may perform the read operations with a voltage higher than the previously used read voltage by 3*qV and a voltage lower than the previously used read voltage by 3*qV in addition to the voltages used when performing the read operations four times.

Hereinafter, a method of operating and outputting the read data after the memory device 100 performs the read operations twice, four times, or six times according to the soft read command SOFTRD_CMD will be described.

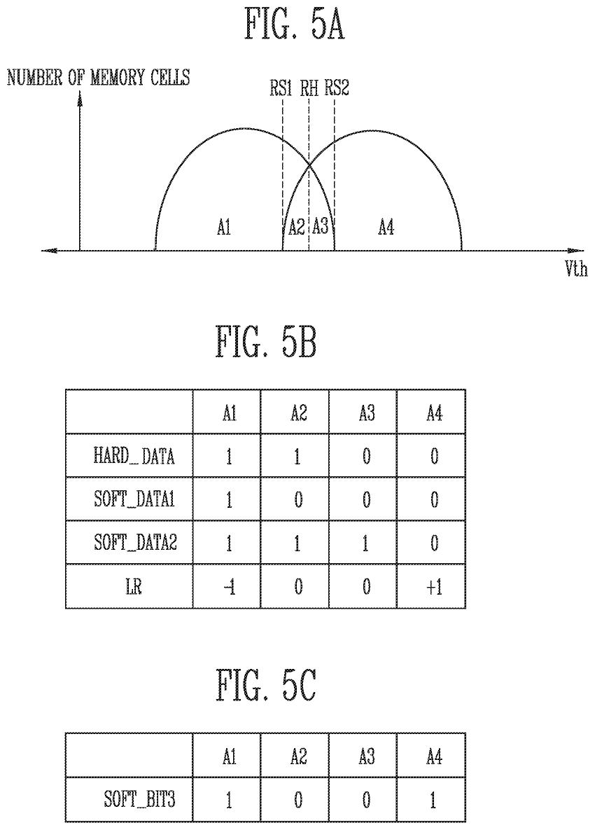

FIGS. 5A, 5B, and 5C are diagrams illustrating the operation of the memory device corresponding to the soft read command in accordance with some embodiments of the present disclosure.

FIG. 5A shows read voltages used in the read operation corresponding to a threshold voltage distribution of the memory cells and the soft read command. FIG. 5B shows read data and likelihood ratio LR generated based on the read data. FIG. 5C shows a soft bit that is a result of the logical operation of the read data performed by the memory device 100 of FIG. 4. The greater the absolute value of the likelihood ratio LR, the higher the reliability of the read data.

Referring to FIG. 5A, FIG. 5A shows an adjacent threshold voltage distribution among threshold voltage distributions of the memory cells. A horizontal axis of FIG. 5A represents a magnitude Vth of the threshold voltage of the memory cells, and a vertical axis of FIG. 5A represents the number of memory cells.

In an embodiment of the present disclosure, when the memory device 100 of FIG. 4 performs the program operation in the same way as a multi-level cell (MLC), FIG. 5A may show the threshold voltage distribution of the memory cells of an erase state E and a first program state P1, the first program state P1 and a second program state P2, or the second program state P2 and a third program state P3 among the erase state E and the first to third program states P1 to P3.

FIG. 5A may also be applicable to a case where the memory device 100 of FIG. 4 performs the program operation in the same way as a single level cell (SLC), triple level cell (TLC), or quadruple level cell (QLC).

In the present drawings, it is assumed that FIG. 5A shows the threshold voltage distribution of the memory cells of the first program state P1 and the second program state P2.

Referring to FIGS. 5A and 5B, the memory device 100 of FIG. 4 may perform the read operation with an RH voltage according to the read command received from the memory controller 200 of FIG. 4. Data read by the RH voltage may be hard data HARD_DATA. When the memory device 100 of FIG. 4 performs the read operation with the RH voltage, since the memory cells of A1 and A2 regions are turned on, the hard data HARD_DATA may be “1”, and since the memory cells of A3 and A4 regions are turned off, the hard data HARD_DATA may be “0”.

When the memory device 100 of FIG. 4 performs the read operation with the RH voltage, the memory cells of the A3 region among the memory cells of the first program state P1 may be turned off (0) due to a change of the threshold voltage. That is, although the memory cell is the first program state P1, when the read operation is performed with the RH voltage, the hard data HARD_DATA may be read as “0”. In addition, when the memory device 100 of FIG. 4 performs the read operation with the RH voltage, the memory cells of the A2 region among the memory cells of the second program state P2 may be turned on (1) due to the change of the threshold voltage. That is, although the memory cell is the second program state P2, when the read operation is performed with the RH voltage, the hard data HARD_DATA may be read as “1”.

Therefore, the error corrector 210 of the memory controller 200 of FIG. 4 may receive data obtained using the RH voltage and perform the first error correction operation on the read data. However, when the first error correction of the data obtained using the RH voltage is failed and the memory device of FIG. 4 receives the soft read command from the memory controller 200 of FIG. 4, the memory device of FIG. 4 may perform the read operation with RS1 and RS2 voltages for the second error correction.

In another embodiment of the present disclosure, the memory device 100 of FIG. 4 may perform the read operations for the second error correction using the RS1 and RS2 voltages and voltages other than the RS1 and RS2 voltages. In the present drawings, it is assumed that the memory device 100 of FIG. 4 performs the read operations with the RS1 and RS2 voltages, that is, two voltages.

Referring to FIG. 5B, the memory device 100 of FIG. 4 may perform the read operation with the RS1 voltage to obtain first soft data SOFT_DATA1 and may perform the read operation with the RS2 voltage to obtain second soft data SOFT_DATA2.

Specifically, when the memory device 100 of FIG. 4 performs the read operation with the RS1 voltage, since the memory cells of the A1 region are turned on, the first soft data SOFT_DATA1 obtained from the memory cells of the A1 region may be “1”. In addition, when the memory device 100 of FIG. 4 performs the read operation with the RS1 voltage, since the memory cells of the A2 to A4 regions are turned off, the first soft data SOFT_DATA1 obtained from the memory cells of the A2 to A4 regions may be “0”.

In an embodiment of the present disclosure, when the memory device 100 of FIG. 4 performs the read operation with the RS2 voltage, since the memory cells of the A1 to A3 regions are turned on, the second soft data SOFT_DATA2 obtained from the memory cells of the A1 to A3 regions may be “1”. In addition, when the memory device 100 of FIG. 4 performs the read operation with the RS2 voltage, since the memory cells of the A4 region are turned off, the second soft data SOFT_DATA2 obtained from the memory cells of the A4 region may be “0”.

According to the conventional art, after the memory device 100 of FIG. 4 performs the read operation according to the soft read command, all read data are output to the memory controller 200 of FIG. 4, and the memory controller 200 of FIG. 4 generates a likelihood ratio LR based on the read data received to perform the error correction operation. That is, in FIG. 5B, the memory controller 200 of FIG. 4 generates the likelihood ratio LR based on the first soft data SOFT_DATA1 and the second soft data SOFT_DATA2 corresponding to the previously read hard data HARD_DATA and the soft read command (−1, 0, 0, +1), and then performs the error correction operation based on the likelihood ratio LR.

However, in accordance with some embodiments of the present disclosure, the memory device 100 of FIG. 4 may not provide both of the first and second soft data SOFT_DATA1 and SOFT_DATA2 to the memory controller 200, but a soft bit obtained by logically operating the first and second soft data SOFT_DATA1 and SOFT_DATA2 to the memory controller 200.

Referring to FIG. 5C, the memory device 100 of FIG. 4 may perform an exclusive-NOR (XNOR) operation on the first and second soft data SOFT_DATA1 and SOFT_DATA2. The XNOR operation may be a match check operation. A result of the XNOR operation on the first and second soft data SOFT_DATA1 and SOFT_DATA2 may be a third soft bit SOFT_BIT3.

Instead of outputting the first and second soft data SOFT_DATA1 and SOFT_DATA2 to the memory controller 200 of FIG. 4, the memory device 100 of FIG. 4 may provide only the third soft bit SOFT_BIT3 to the memory controller 200 of FIG. 4. Therefore, the number of data provided from the memory device 100 of FIG. 4 to the memory controller 200 of FIG. 4 may be reduced. Accordingly, error correction operation efficiency of the memory controller 200 of FIG. 4 may increase.

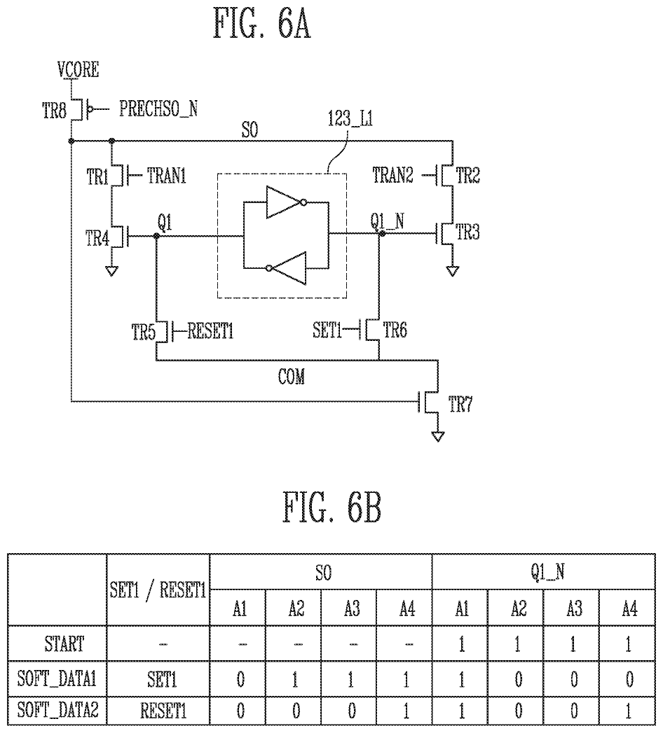

FIGS. 6A and 6B are diagrams illustrating a method of generating the soft bit in accordance with some embodiments of the present disclosure.

Referring to FIGS. 6A and 6B, FIG. 6A shows a part of a configuration of a page buffer included in the page buffer group 123 of FIG. 2 of the memory device 100 of FIG. 2, and FIG. 6B shows the soft bit generated based on the soft read command.

FIG. 6A shows a first page buffer PB1 among a plurality of page buffers included in the page buffer group 123 of FIG. 2. The first page buffer PB1 may include first to eighth transistors TR1 to TR8 and a first latch 123_1. The page buffers other than the first page buffer PB1 may be configured identically to the first page buffer PB1. FIG. 6B shows data on an SO node and a Q1_N node when performing a read operation on the memory cells in the A1 to A4 regions of FIG. 5A.

In an embodiment of the present disclosure, when a first control signal TRAN1 of a high state is applied to a gate of the first transistor TR1, the first transistor TR1 may be turned on. In addition, when a second control signal TRAN2 of a high state is applied to a gate of the second transistor TR2, the second transistor TR2 may be turned on.

In an embodiment of the present disclosure, the third transistor TR3 connected in series with the second transistor TR2 may be connected to the first latch 123_L1 and the sixth transistor TR6 through the Q1_N node, and the third transistor TR3 may be turned on or off based on a signal applied to the Q1_N node. The fourth transistor TR4 connected in series with the first transistor TR1 may be connected to the first latch 123_L1 and the fifth transistor TR5 through the Q1 node, and the fourth transistor TR4 may be turned on or off based on a signal applied to a Q1 node.

In an embodiment of the present disclosure, the fifth transistor TR5 may be connected to the sixth and seventh transistors TR6 and TR7 through a COM node, and when a reset signal RESET1 is applied to a gate of the fifth transistor TR5, the fifth transistor TR5 may be turned on. The sixth transistor TR6 may be connected to the fifth and seventh transistors TR5 and TR7 through the COM node, and when a set signal SET1 of a high state is applied to a gate of the sixth transistor TR6, the sixth transistor TR6 may be turned on.

In an embodiment of the present disclosure, the seventh transistor TR7 may be connected to the fifth and sixth transistors TR5 and TR6 through the COM node, and may be connected to the first, second, and eighth transistors TR1, TR2, and TR8 through the SO node. The seventh transistor TR7 may be turned on or turned off based on a signal applied to the SO node.

In an embodiment of the present disclosure, the eighth transistor TR8 may be connected to the first, second, and seventh transistors TR1, TR2, and TR7 through the SO node. When a sensing node pre-charge signal PRECHSO_N of a low state is applied to a gate of the eighth transistor TR8, the eighth transistor TR8 may be turned on.

In an embodiment of the present disclosure, before the read data read from the memory cell array is stored into the first latch 123_L1, the Q1_N node may be set to “1”, which indicates a default value. Thereafter, when the sensing node pre-charge signal PRECHSO_N is applied to the gate of the eighth transistor TR8, a sensing operation may be started.

Referring to FIG. 5, the memory device 100 of FIG. 4 may perform the read operation with the RS1 voltage according to the soft read command to obtain the first soft data SOFT_DATA1. The first soft data SOFT_DATA1 may be stored into the first latch 123_L1 through the SO node.

Referring to FIGS. 6A and 6B, when the first soft data SOFT_DATA1 is “1”, the inverted “O” may be set in the SO node. That is, when the memory cells of the A1 region are obtained using the RS1 voltage, “O” may be set in the SO node. When “O” is set in the SO node, since the seventh transistor TR7 maintains a turn-off state, the data of the Q1_N node may be maintained as “1”.

On the contrary, when the first soft data SOFT_DATA1 is “0”, the inverted “1” may be set in the SO node. That is, when the memory cells of the A2 to A4 regions are obtained using the RS1 voltage, “1” may be set in the SO node. When “1” is set in the SO node, the seventh transistor TR7 may be turned on. At this time, since the set signal SET1 signal of the high state is applied to the sixth transistor TR6 to connect the Q1_N node and the ground, the data of the Q1_N node may be changed from “1” to “0”.

As a result, when the first soft data SOFT_DATA1 is “1”, the SO node may be set to the inverted “0”, and the data of the Q1_N node may be maintained as “1”. In addition, when the first soft data SOFT_DATA1 is “0”, the SO node may be set to the inverted “1”, and the data of the Q1_N node may be changed to “O”.

Referring to FIG. 5, after performing the read operation with the RS1 voltage, the memory device 100 of FIG. 4 may perform the read operation with the RS2 voltage to obtain the second soft data SOFT_DATA2. The second soft data SOFT_DATA2 may be stored into the first latch 123_L1 through the SO node.

Referring to FIGS. 6A and 6B, when the second soft data SOFT_DATA2 is “1”, the SO node may be set to the inverted “0”. That is, when the memory cells of the A1 to A3 regions are obtained using the RS2 voltage, the SO node may be set to “0”. When the SO node is set to “0”, since the seventh transistor TR7 maintains a turn-off state, the data of the Q1_N node may be maintained without change.

On the contrary, when the second soft data SOFT_DATA2 is “0”, the SO node may be set to the inverted “1”. That is, when the memory cells of the A4 region are obtained using the RS2 voltage, the SO node may be set to “1”. When the SO node is set to “1”, the seventh transistor TR7 may be turned on. At this time, since the reset signal RESET1 of the high state is applied to the fifth transistor TR5 to connect the Q1_N node and ground, the data of the Q1_N node may be changed from “0” to “1” or maintain “1”.

As a result, when the second soft data SOFT_DATA2 is “1”, the SO node may be set to the inverted “0”, and the data of the Q1_N node may be maintained. In addition, when the second soft data SOFT_DATA2 is “0”, the SO node may be set to the inverted “1”, and the data of the Q1_N node may be changed from “0” to “1” or maintain “1”.

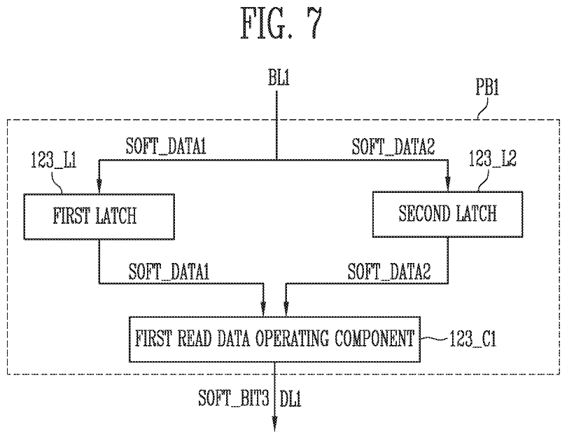

FIG. 7 is a diagram illustrating the method of generating the soft bit in accordance with some embodiments of the present disclosure.

Referring to FIG. 7, FIG. 7 shows a first page buffer PB1 among the page buffers included in the page buffer group 123 of FIG. 2. The first page buffer PB1 of FIG. 7 may include a first latch 123_L1, a second latch 123_L2, and a first read data operating component 123_C1. In another embodiment of the present disclosure, the first page buffer PB1 may include more latches. In addition, the descriptions below may be applied to other page buffers included in the page buffer group 123 of FIG. 2.

In an embodiment of the present disclosure, the memory device 100 of FIG. 4 may perform the read operation corresponding to the soft read command received from the memory controller 200 of FIG. 4 to receive the soft data through the first bit line BL1.

Referring to FIG. 5A, the first soft data SOFT_DATA1 obtained from the read operation performed by the memory device 100 of FIG. 4 with the RS1 voltage, may be stored into the first latch 123_L1, and the second soft data SOFT_DATA2 obtained from the read operation performed by the memory device 100 of FIG. 4 with the RS2 voltage, may be stored into the second latch 123_L2. That is, the memory device 100 of FIG. 4 may perform the read operations with the RS1 voltage and the RS2 voltage in correspondence with the soft read command to store the read data obtained from the read operations into the respective latches.

The first and second soft data SOFT_DATA1 and SOFT_DATA2 stored in the first and second latches 123_L1 and 123_L2, respectively, may be outputted to the first read data operating component 123_C1. The first read data operating component 123_C1 may receive the first and second soft data SOFT_DATA1 and SOFT_DATA2 to perform an XNOR operation thereon. The XNOR operation may be a match check operation. The first read data operating component 123_C1 may perform the XNOR operation on the first and second soft data SOFT_DATA1 and SOFT_DATA2 to generate a third soft bit SOFT_BIT3 (i.e., a result of XNOR operation on the first and second soft data), and may output the third soft bit SOFT_BIT3 to the column decoder 124 of FIG. 2 through the first data line DL1.

Referring to FIG. 7, the memory device 100 of FIG. 4 may provide only the third soft bit SOFT_BIT3 to the memory controller 200 of FIG. 4 instead of outputting both of the first and second soft data SOFT_DATA1 and SOFT_DATA2, to the memory controller 200 of FIG. 4. Therefore, the number of data provided from the memory device 100 of FIG. 4 to the memory controller 200 of the FIG. 4 may be reduced. Further, since the memory device 100 of FIG. 4 performs the logical operation for the second error correction, the efficiency of the error correction operation of the memory controller 200 of FIG. 4 may be increased.

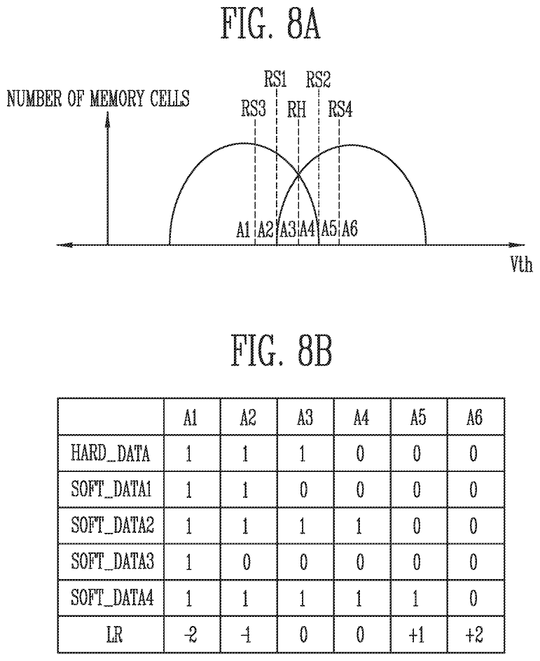

FIGS. 8A and 8B are diagrams illustrating the operation of the memory device corresponding to the soft read command in accordance with some embodiments of the present disclosure.

Referring to FIGS. 8A and 8B, FIG. 8A shows read voltages used in the read operation corresponding to the threshold voltage distribution of the memory cells and the soft read command, and FIG. 8B shows read data and likelihood ratio LR generated based on the read data. The greater the absolute value of the likelihood ratio LR, the higher the reliability of the read data.

Referring to FIGS. 5A and 8A, FIG. 8A shows a case where a read operation is additionally performed with an RS3 voltage and an RS4 voltage as well as the read voltages of FIG. 5A.

In an embodiment of the present disclosure, as the number of bits stored in one memory cell increases, it is highly possible that an error is included in the read data. That is, as the threshold voltage distribution of the memory cells is segmented, adjacent threshold voltage distributions may be overlap due to temperature and retention. Therefore, in order to correct the error of the read data, a greater number of read operations may be performed according to the soft read command.

FIG. 8A is assumed to illustrate the threshold voltage distribution of the memory cells of the first program state P1 and the second program state P2 similarly to FIG. 5A. That is, FIG. 8A shows an adjacent threshold voltage distribution among threshold voltage distributions of the memory cells. A horizontal axis of FIG. 8A represents a magnitude Vth of the threshold voltage of the memory cells, and a vertical axis of FIG. 8A represents the number of memory cells.

Hereinafter, description repetitive to that of FIG. 5A will be omitted for clarity.

Referring to FIGS. 8A and 8B, the memory device 100 of FIG. 4 may perform the read operation with the RH voltage according to the read command received from the memory controller 200 of FIG. 4. Data by the RH voltage may be the hard data HARD_DATA. When the memory device 100 of FIG. 4 performs the read operation with the RH voltage, since the memory cells of A1 to A3 regions are turned on, the hard data HARD_DATA may be “1”, and since the memory cells of A4 to A6 regions are turned off, the hard data HARD_DATA may be “0”.

When the memory device 100 of FIG. 4 performs the read operation with the RH voltage, the memory cells of the A4 region among the memory cells of the first program state P1 may be turned off (0) due to a change of the threshold voltage. That is, although the memory cell is the first program state P1, when the read operation is performed with the RH voltage, the hard data HARD_DATA may be read as “0”. In addition, when the memory device 100 of FIG. 4 performs the read operation with the RH voltage, the memory cells of the A3 region among the memory cells of the second program state P2 may be turned on (1) due to the change of the threshold voltage. That is, although the memory cell is the second program state P2, when the read operation is performed with the RH voltage, the hard data HARD_DATA may be read as “1”.

Therefore, the error corrector 210 of FIG. 4 included in the memory controller 200 of FIG. 4 may receive the data obtained using the RH voltage and perform the first error correction operation on the read data. However, if the first error correction of data obtained using the RH voltage is failed, the memory device of FIG. 4 may receive the soft read command from the memory controller 200 of FIG. 4. In the present drawings, it is assumed that the memory device 100 of FIG. 4 performs the read operations with the RS1 to RS4 voltages according to the soft read command for the second error correction.

Referring to FIG. 8B, the memory device 100 of FIG. 4 may perform the read operation with the RS1 voltage to obtain the first soft data SOFT_DATA1, may perform the read operation with the RS2 voltage to obtain the second soft data SOFT_DATA2, may perform the read operation with the RS3 voltage to obtain third soft data SOFT_DATA3, and may perform the read operation with the RS4 voltage to obtain fourth soft data SOFT_DATA4.

Specifically, when the memory device 100 of FIG. 4 performs the read operation with the RS1 voltage, since the memory cells of the A1 and A2 regions are turned on, the first soft data SOFT_DATA1 obtained from the memory cells of the A1 and A2 regions may be “1”. In addition, when the memory device 100 of FIG. 4 performs the read operation with the RS1 voltage, since the memory cells of the A3 to A6 regions are turned off, the first soft data SOFT_DATA1 obtained from the memory cells of the A3 to A6 regions may be “0”.

In an embodiment of the present disclosure, when the memory device 100 of FIG. 4 performs the read operation with the RS2 voltage, since the memory cells of the A1 to A4 regions are turned on, the second soft data SOFT_DATA2 obtained from the memory cells of the A1 to A4 regions may be “1”. In addition, when the memory device 100 of FIG. 4 performs the read operation with the RS2 voltage, since the memory cells of the A5 and A6 regions are turned off, the second soft data SOFT_DATA2 obtained from the memory cells of the A5 and A6 regions may be “O”.

In an embodiment of the present disclosure, when the memory device 100 of FIG. 4 performs the read operation with the RS3 voltage, since the memory cells of the A1 region are turned on, the third soft data SOFT_DATA3 obtained from the memory cells of the A1 region may be “1”. In addition, when the memory device 100 of FIG. 4 performs the read operation with the RS3 voltage, since the memory cells of the A2 and A6 regions are turned off, the third soft data SOFT_DATA3 obtained from the memory cells of the A2 and A6 regions may be “0”.

In an embodiment of the present disclosure, when the memory device 100 of FIG. 4 performs the read operation with the RS4 voltage, since the memory cells of the A1 to A5 region are turned on, the fourth soft data SOFT_DATA4 obtained from the memory cells of the A1 to A5 region may be “1”. In addition, when the memory device 100 of FIG. 4 performs the read operation with the RS4 voltage, since the memory cells of the A6 region are turned off, the fourth soft data SOFT_DATA4 obtained from the memory cells of the A6 region may be “0”.

As a result, when the first error correction of the read data is failed after the read operation is performed with the RH voltage, the memory device 100 of FIG. 4 may perform the read operation with the RS1 to RS4 voltages for the second error correction, and the memory controller 200 of FIG. 4 may generate likelihood ratio LR based on the read data obtained using the RS1 to RS4 voltages (−2, −1, 0, 0, +1, +2). Thereafter, the memory controller 200 of FIG. 4 may perform the second error correction of the read data based on the likelihood ratio LR again.

However, in the present disclosure, the memory device 100 of FIG. 4 may not provide all of the first to fourth soft data SOFT_DATA1 to SOFT_DATA4 to the memory controller 200 of FIG. 4. Instead, the memory device 100 of FIG. 4 may provide the soft bit obtained by performing the XNOR operation on the first to fourth soft data SOFT_DATA1 to SOFT_DATA4 to the memory controller 200 of FIG. 4. When the memory device 100 of FIG. 4 performs the XNOR operation on the first to fourth soft data SOFT_DATA1 to SOFT_DATA4, the memory device 100 of FIG. 4 may provide only two soft bits to the memory controller 200 of FIG. 4.

Hereinafter, the two soft bits provided by the memory device 100 of FIG. 4 will be described.

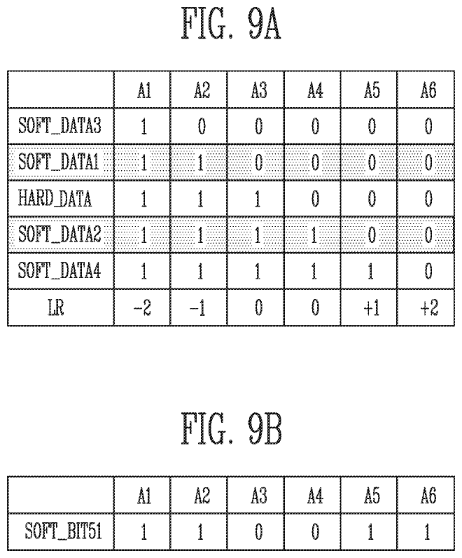

FIGS. 9A and 9B are diagrams illustrating the soft bit generated according to the operation of the memory device of FIG. 8 in accordance with some embodiments of the present disclosure.

Referring to FIGS. 8A, 8B, 9A, and 9B, FIG. 9A shows a table in which a table of FIG. 8B is sequentially arranged from read data obtained using the lowest read voltage, and FIG. 9B shows the soft bits generated based on the first and second soft data SOFT_DATA1 and SOFT_DATA2. Since FIG. 9A is substantially the same table as FIG. 8B, the description of FIG. 9A will be omitted for clarity.

Referring to FIG. 9B, FIG. 9B shows a fifty-first soft bit SOFT_BIT51 which indicates data obtained by performing the XNOR operation on the first and second soft data SOFT_DATA1 and SOFT_DATA2. The XNOR operation may be a match check operation.

In an embodiment of the present disclosure, the first soft data SOFT_DATA1 may be obtained by the memory device 100 of FIG. 4 by reading from the memory cells of the A1 and A2 regions with the RS1 voltage, and the second soft data SOFT_DATA2 may be obtained by the memory device 100 of FIG. 4 by reading from the memory cells of the A1 and A2 regions with the RS2 voltage. Both of the first soft data SOFR_DATA1 and the second soft data SOFT_DATA2 may be “1”. Therefore, the data obtained by performing the XNOR operation on the first and second soft data SOFT_DATA1 and SOFT_DATA2 may be “1”.

In an embodiment of the present disclosure, the first soft data SOFT_DATA1 that the memory device 100 of FIG. 4 may obtain by reading from the memory cells of the A3 and A4 regions with the RS1 voltage may be “0”, and the second soft data SOFT_DATA2 that the memory device 100 of FIG. 4 may obtain by reading from the memory cells of the A3 and A4 regions with the RS2 voltage may be “1”. Therefore, the data obtained by performing the XNOR operation on the first and second soft data SOFT_DATA1 and SOFT_DATA2 may be “0”.

In an embodiment of the present disclosure, both of the first soft data SOFT_DATA1 that the memory device 100 of FIG. 4 may obtain by reading from the memory cells of the A5 and A6 regions with the RS1 voltage, and the second soft data SOFT_DATA2 that the memory device 100 of FIG. 4 may obtain by reading from the memory cells of the A5 and A6 regions with the RS2 voltage, may be “0”. Therefore, the data obtained by performing the XNOR operation on the first and second soft data SOFT_DATA1 and SOFT_DATA2 may be “1”.

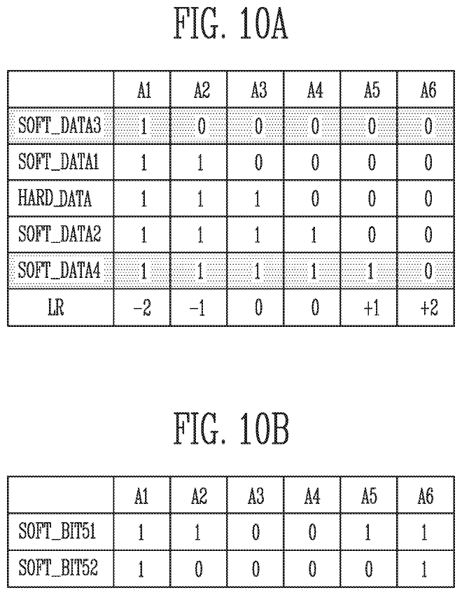

FIGS. 10A and 10B are diagrams illustrating another soft bit generated by the operation of the memory device of FIGS. 8A and 8B in accordance with some embodiments of the present disclosure.

Referring to FIGS. 10A and 10B, FIG. 10A shows the same table as the table of FIG. 9A, and FIG. 10B shows the fifty-first soft bit SOFT_BIT51 generated based on the first and second soft data SOFT_DATA1 and SOFT_DATA2, and fifty-second soft bit SOFT_BIT52 generated based on the third and fourth soft data SOFT_DATA3 and SOFT_DATA4.

Since the fifty-first soft bit SOFT_BIT51 of FIGS. 10A and 10B are the same as the fifty-first soft bit SOFT_BIT51 of FIGS. 9A and 9B, respectively, description repetitive to the description of FIG. 9 will be omitted for clarity.

Referring to FIG. 10B, second column shows the fifty-second soft bit SOFT_BIT52 which indicates data obtained by performing the XNOR operation on the third and fourth soft data SOFT_DATA3 and SOFT_DATA4. The XNOR operation may be a match check operation.

In an embodiment of the present disclosure, both of the third soft data SOFT_DATA3 obtained by the memory device 100 of FIG. 4 by reading from the memory cells of the A1 region with the RS3 voltage, and the fourth soft data SOFT_DATA4 obtained by the memory device 100 of FIG. 4 by reading from the memory cells of the A1 region with the RS4 voltage, may be “1”. Therefore, the data obtained by performing the XNOR operation on the third and fourth soft data SOFT_DATA3 and SOFT_DATA4 may be “1”.

In an embodiment of the present disclosure, the third soft data SOFT_DATA3 obtained by the memory device 100 of FIG. 4 by reading from the memory cells of the A2 to A5 regions with the RS3 voltage may be “0”, and the fourth soft data SOFT_DATA4 obtained by the memory device 100 of FIG. 4 by reading from the memory cells of the A2 to A5 regions with the RS4 voltage may be “1”. Therefore, the data obtained by performing the XNOR operation on the third and fourth soft data SOFT_DATA3 and SOFT_DATA4 may be “0”.

In an embodiment of the present disclosure, both of the third soft data SOFT_DATA3 obtained by the memory device 100 of FIG. 4 by reading from the memory cells of the A6 region with the RS3 voltage, and the fourth soft data SOFT_DATA4 obtained by the memory device 100 of FIG. 4 by reading from the memory cells of the A6 region with the RS4 voltage, may be “0”. Therefore, the data obtained by performing the XNOR operation on the third and fourth soft data SOFT_DATA3 and SOFT_DATA4 may be “1”.

When the memory device 100 of FIG. 4 generates the fifty-first and fifty-second soft bits SOFT_BIT51 and SOFT_BIT52 by performing the XNOR operation based on the first to fourth soft data SOFT_DATA1 to SOFT_DATA4, the memory device 100 of FIG. 4 may output the fifty-first and fifty-second soft bits SOFT_BIT51 and SOFT_BIT52 to the memory controller 200 of FIG. 4. Therefore, the memory device 100 of FIG. 4 may provide only the fifty-first and fifty-second soft bits SOFT_BIT51 and SOFT_BIT52 to the memory controller 200 of FIG. 4 instead of providing all of the first to fourth soft data SOFT_DATA1 to SOFT_DATA4 to the memory controller 200 of FIG. 4.

As a result, the number of data provided from the memory device 100 of FIG. 4 to the memory controller 200 of FIG. 4 may be reduced. Further, the memory device 100 of FIG. 4 performs the logical operation for the second error correction Instead of the memory controller 200 of FIG. 4. Thus, the error correction efficiency of the memory controller 200 of FIG. 4 may be increased.

Although not shown in the present drawings, the memory device 100 of FIG. 4 may perform the XNOR on the fifty-first and fifty-second soft bits SOFT_BIT51 and SOFT_BIT52. That is, the memory device 100 of FIG. 4 may provide only data obtained by performing the XNOR operation on the fifty-first and fifty-second soft bits SOFT_BIT51 and SOFT_BIT52 to the memory controller 200 of FIG. 4 instead of providing the fifty-first and fifty-second soft bits SOFT_BIT51 and SOFT_BIT52 generated based on the first to fourth soft data SOFT_DATA1 to SOFT_DATA4 to the memory controller 200 of FIG. 4. Therefore, since the memory device 100 of FIG. 4 outputs a smaller number of data to the memory controller 200 of FIG. 4, the error correction efficiency of the memory controller 200 of FIG. 4 may be increased.

In addition, although not shown in the present drawings, the read operation may be performed with RS1 to RS8 voltages, that is, eight voltages, according to the soft read command for the second error correction. In this case, the memory device 100 of FIG. 4 may obtain first to eighth soft data SOFT_DATA1 to SOFT_DATA8 by performing the read operation with the RS1 to RS8 voltages. When the first to eighth soft data SOFT_DATA1 to SOFT_DATA8 are obtained, the memory device 100 of FIG. 4 may not provide all of the first to eighth soft data SOFT_DATA1 to SOFT_DATA8 to the memory controller 200 of FIG. 4 but four soft bits obtained by performing XNOR operation on the first to eighth soft data SOFT_DATA1 to SOFT_DATA8 to the memory controller 200 of FIG. 4.

In an embodiment of the present disclosure, when the memory device 100 of FIG. 4 performs the read operation with the RS1 to RS8 voltages, the memory device 100 of FIG. 4 may provide fifty-first soft bit SOFT_BIT51, which is data obtained by performing the XNOR operation on the first and second soft data SOFT_DATA1 and SOFT_DATA2, fifty-second soft bit SOFT_BIT52, which is data obtained by performing the XNOR operation on the third and fourth soft data SOFT_DATA3 and SOFT_DATA4, fifty-third soft bit SOFT_BIT53, which is data obtained by performing the XNOR operation on the fifth and sixth soft data SOFT_DATA5 and SOFT_DATA6, and fifty-fourth soft bit SOFT_BIT54, which is data obtained by performing the XNOR operation on the seventh and eighth soft data SOFT_DATA7 and SOFT_DATA8, to the memory controller 200 of FIG. 4.

In an embodiment of the present disclosure, when the memory device 100 of FIG. 4 performs the read operation with the RS1 to RS8 voltages, the memory device 100 of FIG. 4 may provide data obtained by performing the XNOR operation on the fifty-first soft bit SOFT_BIT51 and the fifty-fourth soft bit SOFT_BIT54, and data obtained by performing the XNOR operation on the fifty-second soft bit SOFT_BIT52 and the fifty-third soft bit SOFT_BIT53, to the memory controller 200 of FIG. 4. That is, instead of providing the fifty-first to fifty-fourth soft bits SOFT_BIT51 to SOFT_BIT54 to the memory controller 200 of FIG. 4, the only two data obtained by performing the XNOR operation on the fifty-first to fifty-fourth soft bits SOFT_BIT51 to SOFT_BIT54 may be provided to the memory controller 200 of FIG. 4. Furthermore, the memory device 100 of FIG. 4 may also output only one data obtained by performing the XNOR operation on the two data obtained by performing the XNOR operation on the fifty-first to fifty-fourth soft bits SOFT_BIT51 to SOFT_BIT54, to the memory controller 200 of FIG. 4.

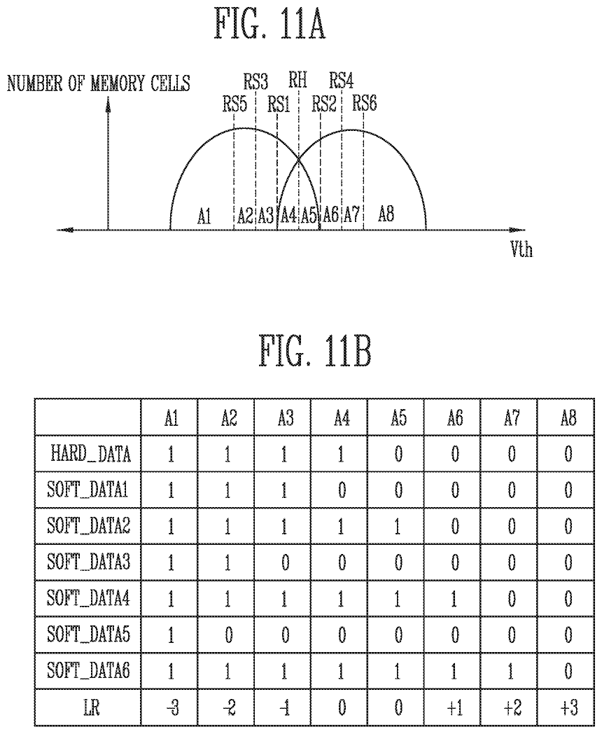

FIGS. 11A and 11B are diagrams illustrating the operation of the memory device corresponding to the soft read command in accordance with some embodiments of the present disclosure.

Referring to FIGS. 11A and 11B, FIG. 11A shows read voltages used in the read operation corresponding to the threshold voltage distribution of the memory cells and the soft read command, and FIG. 11B shows read data and likelihood ratio LR generated based on the read data. The greater the absolute value of the likelihood ratio LR, the higher the reliability of the read data.

Referring to FIGS. 8A and 11A, FIG. 11A shows a case where a read operation is additionally performed with an RS5 voltage and an RS6 voltage in addition to the read voltages of FIG. 8A.

FIG. 11A is assumed to illustrate the threshold voltage distribution of the memory cells of the first program state P1 and the second program state P2 similarly to FIG. 8A. A horizontal axis of FIG. 11A represents a magnitude Vth of the threshold voltage of the memory cells, and a vertical axis of FIG. 11A represents the number of memory cells.

Hereinafter, description repetitive to that of FIG. 8A will be omitted for clarity.

Referring to FIGS. 11A and 11B, the memory device 100 of FIG. 4 may perform the read operation with the RH voltage according to the read command received from the memory controller 200 of FIG. 4. The read data obtained using the RH voltage may be the hard data HARD_DATA. When the memory device 100 of FIG. 4 performs the read operation with the RH voltage, since the memory cells of A1 to A4 regions are turned on, the hard data HARD_DATA may be “1”, and since the memory cells of A5 to A8 regions are turned off, the hard data HARD_DATA may be “0”.

When the memory device 100 of FIG. 4 performs the read operation with the RH voltage, the memory cells of the A5 region among the memory cells of the first program state P1 may be turned off (0) due to a change of the threshold voltage. That is, although the memory cell is the first program state P1, when the read operation is performed with the RH voltage, the hard data HARD_DATA may be read as “0”. In addition, when the memory device 100 of FIG. 4 performs the read operation with the RH voltage, the memory cells of the A4 region among the memory cells of the second program state P2 may be turned on (1) due to the change of the threshold voltage. That is, although the memory cell is the second program state P2, when the read operation is performed with the RH voltage, the hard data HARD_DATA may be read as “1”.

Therefore, the error corrector 210 of FIG. 4 included in the memory controller 200 of FIG. 4 may receive the read data obtained using the RH voltage and perform the first error correction operation. However, when the error correction of the read data obtained using the RH voltage is failed, the memory device of FIG. 4 may receive the soft read command from the memory controller 200 of FIG. 4. In the present drawings, it is assumed that the memory device 100 of FIG. 4 performs the read operation with the RS1 to RS4 voltages according to the soft read command for the second error correction.

Referring to FIG. 11B, the memory device 100 of FIG. 4 may perform the read operation with the RS1 voltage to obtain the first soft data SOFT_DATA1, may perform the read operation with the RS2 voltage to obtain the second soft data SOFT_DATA2, may perform the read operation with the RS3 voltage to obtain third soft data SOFT_DATA3, may perform the read operation with the RS4 voltage to obtain fourth soft data SOFT_DATA4, may perform the read operation with the RS5 voltage to obtain fifth soft data SOFT_DATA5, and may perform the read operation with the RS6 voltage to obtain sixth soft data SOFT_DATA6.

Specifically, when the memory device 100 of FIG. 4 performs the read operation with the RS1 voltage, since the memory cells of the A1 to A3 regions are turned on, the first soft data SOFT_DATA1 obtained by reading from the memory cells of the A1 to A3 regions may be “1”. In addition, when the memory device 100 of FIG. 4 performs the read operation with the RS1 voltage, since the memory cells of the A4 to A8 regions are turned off, the first soft data SOFT_DATA1 obtained by reading from the memory cells of the A4 to A8 regions may be “0”.

In an embodiment of the present disclosure, when the memory device 100 of FIG. 4 performs the read operation with the RS2 voltage, since the memory cells of the A1 to A5 regions are turned on, the second soft data SOFT_DATA2 obtained by reading from the memory cells of the A1 to A5 regions may be “1”. In addition, when the memory device 100 of FIG. 4 performs the read operation with the RS2 voltage, since the memory cells of the A6 to A8 regions are turned off, the second soft data SOFT_DATA2 obtained by reading from the memory cells of the A6 to A8 regions may be “0”.

In an embodiment of the present disclosure, when the memory device 100 of FIG. 4 performs the read operation with the RS3 voltage, since the memory cells of the A1 and A2 regions are turned on, the third soft data SOFT_DATA3 obtained by reading from the memory cells of the A1 and A2 regions may be “1”. In addition, when the memory device 100 of FIG. 4 performs the read operation with the RS3 voltage, since the memory cells of the A3 to A8 regions are turned off, the third soft data SOFT_DATA3 obtained by reading from the memory cells of the A3 to A8 regions may be “0”.

In an embodiment of the present disclosure, when the memory device 100 of FIG. 4 performs the read operation with the RS4 voltage, since the memory cells of the A1 to A6 regions are turned on, the fourth soft data SOFT_DATA4 obtained by reading from the memory cells of the A1 to A6 regions may be “1”. In addition, when the memory device 100 of FIG. 4 performs the read operation with the RS4 voltage, since the memory cells of the A7 and A8 regions are turned off, the fourth soft data SOFT_DATA4 obtained by reading from the memory cells of the A7 and A8 regions may be “0”.

In an embodiment of the present disclosure, when the memory device 100 of FIG. 4 performs the read operation with the RS5 voltage, since the memory cells of the A1 region are turned on, the fifth soft data SOFT_DATA5 obtained by reading from the memory cells of the A1 region may be “1”. In addition, when the memory device 100 of FIG. 4 performs the read operation with the RS5 voltage, since the memory cells of the A2 to A8 regions are turned off, the fifth soft data SOFT_DATA5 obtained by reading from the memory cells of the A2 to A8 regions may be “0”.

In an embodiment of the present disclosure, when the memory device 100 of FIG. 4 performs the read operation with the RS6 voltage, since the memory cells of the A1 to A7 regions are turned on, the sixth soft data SOFT_DATA6 obtained by reading from the memory cells of the A1 to A7 regions may be “1”. In addition, when the memory device 100 of FIG. 4 performs the read operation with the RS6 voltage, since the memory cells of the A8 region are turned off, the sixth soft data SOFT_DATA6 obtained by reading from the memory cells of the A8 region may be “0”.

As a result, if the first error correction of the read data is failed after the read operation is performed with the RH voltage, the memory device 100 of FIG. 4 may perform the read operation with the RS1 to RS6 voltages. Then, the memory controller 200 of FIG. 4 may generate likelihood ratio LR based on the data obtained using the RS1 to RS6 voltages (−3, −2, −1, 0, 0, +1, +2). Thereafter, the memory controller 200 of FIG. 4 may perform the second error correction of the read data based on the likelihood ratio LR again.

However, in accordance with some embodiments of the present disclosure, the memory device 100 of FIG. 4 may not provide all of the first to sixth soft data SOFT_DATA1 to SOFT_DATA6 to the memory controller 200 of FIG. 4, and may provide the soft bit obtained by performing the XNOR operation on the first to sixth soft data SOFT_DATA1 to SOFT_DATA6 to the memory controller 200 of FIG. 4. When the memory device 100 of FIG. 4 performs the XNOR operation on the first to sixth soft data SOFT_DATA1 to SOFT_DATA6, the memory device 100 of FIG. 4 may provide only two or three soft bits to the memory controller 200 of FIG. 4.

Hereinafter, the two or three soft bits output by the memory device 100 of FIG. 4 will be described.

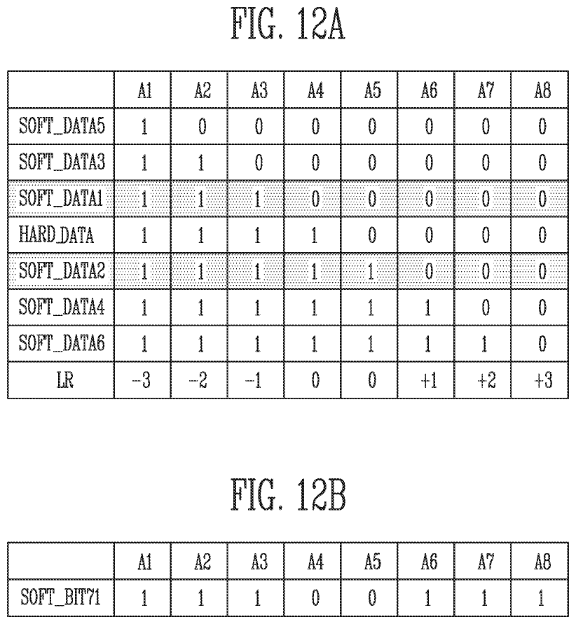

FIGS. 12A and 12B are diagrams illustrating the soft bit generated according to the operation of the memory device of FIG. 11 in accordance with some embodiments of the present disclosure.

Referring to FIGS. 11A, 11B, 12A, and 12B, FIG. 12A shows a table in which a table of FIG. 11B is sequentially arranged from read data obtained using the lowest read voltage, and FIG. 12B shows the soft bits generated based on the first and second soft data SOFT_DATA1 and SOFT_DATA2. Since FIG. 12A is substantially the same table as FIG. 11B, the description of FIG. 12A will be omitted for clarity.

Referring to FIG. 12B, FIG. 12B shows a seventy-first soft bit SOFT_BIT71 obtained by performing the XNOR operation on the first and second soft data SOFT_DATA1 and SOFT_DATA2. The XNOR operation may be a match check operation.

In an embodiment of the present disclosure, both of the first soft data SOFT_DATA1 obtained by the memory device 100 of FIG. 4 by reading from the memory cells of the A1 to A3 regions with the RS1 voltage, and the second soft data SOFT_DATA2 obtained by the memory device 100 of FIG. 4 by reading from the memory cells of the A1 to A3 regions with the RS2 voltage, may be “1”. Therefore, the data obtained by performing the XNOR operation on the first and second soft data SOFT_DATA1 and SOFT_DATA2 may be “1”.

In an embodiment of the present disclosure, the first soft data SOFT_DATA1, which is obtained by the memory device 100 of FIG. 4 by reading from the memory cells of the A4 and A5 regions with the RS1 voltage may be “0”, and the second soft data SOFT_DATA2, which is obtained by the memory device 100 of FIG. 4 by reading from the memory cells of the A4 and A5 regions with the RS2 voltage may be “1”. Therefore, the data obtained by performing the XNOR operation on the first and second soft data SOFT_DATA1 and SOFT_DATA2 may be “0”.

In an embodiment of the present disclosure, both of the first soft data SOFT_DATA1 obtained by the memory device 100 of FIG. 4 by reading from the memory cells of the A6 to A8 regions with the RS1 voltage, and the second soft data SOFT_DATA2 obtained by the memory device 100 of FIG. 4 by reading from the memory cells of the A6 to A8 regions with the RS2 voltage, may be “0”. Therefore, the data obtained by performing the XNOR operation on the first and second soft data SOFT_DATA1 and SOFT_DATA2 may be “1”.

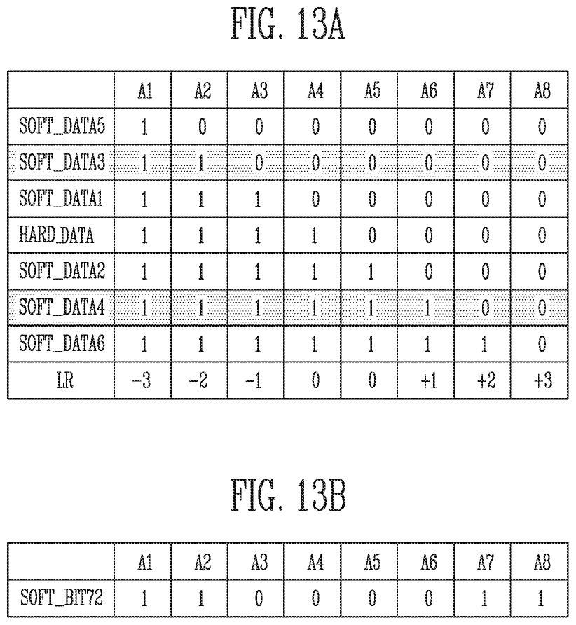

FIGS. 13A and 13B are diagrams illustrating another soft bit generated by the operation of the memory device of FIGS. 11A and 11B in accordance with some embodiments of the present disclosure.

Referring to FIGS. 11A to 13B, FIG. 13A shows the same table as the table of FIG. 12A, and FIG. 13B shows the soft bit generated based on the third and fourth soft data SOFT_DATA3 and SOFT_DATA4. Since FIG. 13A is the same table as FIG. 12A, description of FIG. 13A will be omitted.

Referring to FIG. 13B, FIG. 13B shows seventy-second soft bit SOFT_BIT72 obtained by performing the XNOR operation on the third and fourth soft data SOFT_DATA3 and SOFT_DATA4. The XNOR operation may be a match check operation.

In an embodiment of the present disclosure, both of the third soft data SOFT_DATA3, which is obtained by the memory device 100 of FIG. 4 by reading from the memory cells of the A1 and A2 regions with the RS3 voltage, and the fourth soft data SOFT_DATA4, which is obtained by the memory device 100 of FIG. 4 by reading from the memory cells of the A1 and A2 regions with the RS4 voltage, may be “1”. Therefore, the data obtained by performing the XNOR operation on the third and fourth soft data SOFT_DATA3 and SOFT_DATA4 may be “1”.

In an embodiment of the present disclosure, the third soft data SOFT_DATA3, which is obtained by the memory device 100 of FIG. 4 by reading from the memory cells of the A3 to A6 regions with the RS3 voltage may be “0”, and the fourth soft data SOFT_DATA4, which is obtained by the memory device 100 of FIG. 4 by reading from the memory cells of the A3 to A6 regions with the RS4 voltage may be “1”. Therefore, the data obtained by performing the XNOR operation on the third and fourth soft data SOFT_DATA3 and SOFT_DATA4 may be “0”.

In an embodiment of the present disclosure, both of the third soft data SOFT_DATA3, which is obtained by the memory device 100 of FIG. 4 reading from the memory cells of the A7 and A8 regions with the RS3 voltage, and the fourth soft data SOFT_DATA4, which is obtained by the memory device 100 of FIG. 4 by reading from the memory cells of the A7 and A8 regions with the RS4 voltage, may be “0”. Therefore, the data obtained by performing the XNOR operation on the third and fourth soft data SOFT_DATA3 and SOFT_DATA4 may be “1”.

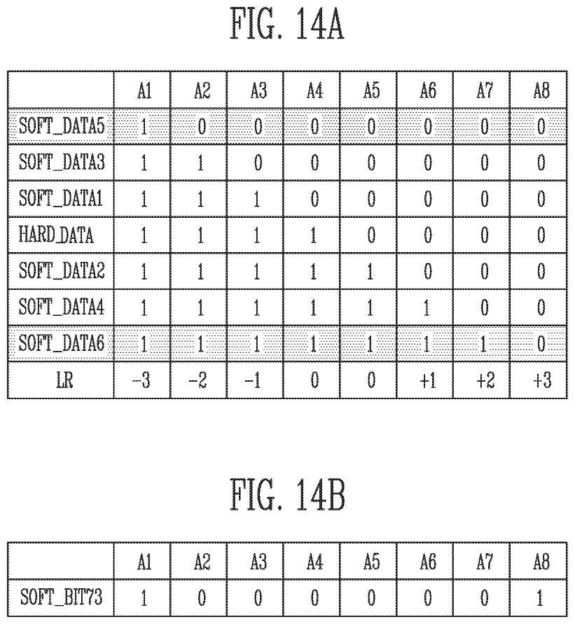

FIGS. 14A and 14B are diagrams illustrating another soft bit generated by the operation of the memory device of FIGS. 11A and 11B in accordance with some embodiments of the present disclosure.

Referring to FIGS. 11A to 14B, FIG. 14A shows the same table as the table of FIG. 12A and FIG. 13A, and FIG. 14B shows the soft bit generated based on the fifth and sixth soft data SOFT_DATA5 and SOFT_DATA6. Since FIG. 14A is the same table as FIG. 12A and FIG. 13A, description of FIG. 14A will be omitted for clarity.

Referring to FIG. 14B, FIG. 14B shows seventy-third soft bit SOFT_BIT73 obtained by performing the XNOR operation on the fifth and sixth soft data SOFT_DATA5 and SOFT_DATA6.

In an embodiment of the present disclosure, both of the fifth soft data SOFT_DATA5, which is obtained by the memory device 100 of FIG. 4 by reading from the memory cells of the A1 region with the RS5 voltage, and the sixth soft data SOFT_DATA6, which is obtained by the memory device 100 of FIG. 4 by reading from the memory cells of the A1 region with the RS6 voltage, may be “1”. Therefore, the data obtained by performing the XNOR operation on the fifth and sixth soft data SOFT_DATA5 and SOFT_DATA6 may be “1”.

In an embodiment of the present disclosure, the fifth soft data SOFT_DATA5, which is obtained by the memory device 100 of FIG. 4 by reading from the memory cells of the A2 to A7 regions with the RS5 voltage may be “0”, and the sixth soft data SOFT_DATA6, which is obtained by the memory device 100 of FIG. 4 by reading from the memory cells of the sixth soft data SOFT_DATA6 regions with the RS6 voltage may be “1”. Therefore, the data obtained by performing the XNOR operation on the fifth and sixth soft data SOFT_DATA5 and SOFT_DATA6 may be “0”.

In an embodiment of the present disclosure, both of the fifth soft data SOFT_DATA5, which is obtained by the memory device 100 of FIG. 4 by reading from the memory cells of the A8 region with the RS5 voltage, and the sixth soft data SOFT_DATA6, which is obtained by the memory device 100 of FIG. 4 by reading from the memory cells of the A8 region with the RS6 voltage, may be “0”. Therefore, the data obtained by performing the XNOR operation on the fifth and sixth soft data SOFT_DATA5 and SOFT_DATA6 may be “1”.

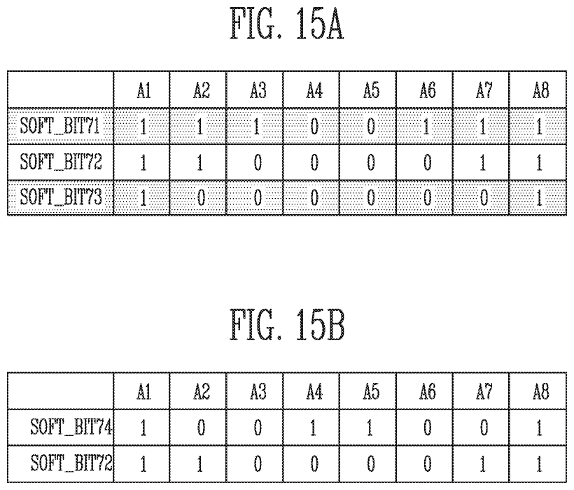

FIGS. 15A and 15B are diagrams Illustrating the soft bit output according to the operation of the memory device of FIG. 11 in accordance with some embodiments of the present disclosure.

Referring to FIGS. 12A to 15B, FIG. 15A shows the seventy-first soft bit SOFT_BIT71 of FIG. 12B, the seventy-second soft bit SOFT_BIT72 of FIG. 13B, the seventy-third soft bit SOFT_BIT73 of FIG. 14B, and FIG. 15B shows a soft bit newly generated based on the soft bits.

Referring to FIG. 15A, the memory device 100 of FIG. 4 may perform the read operation with the RS1 to RS6 voltages according to the soft read command received from the memory controller 200 of FIG. 4, perform the XNOR operation on the read first to sixth soft data SOFT_DATA1 to SOFT_DATA6, and generate the seventy-first to seventy-third soft bits SOFT_BIT71 to SOFT_BIT73.

As a result, the memory device 100 of FIG. 4 may provide only the seventy-first to seventy-third soft bits SOFT_BIT71 to SOFT_BIT73 to the memory controller 200 of FIG. 4 instead of providing all of the first to sixth soft data SOFT_DATA1 to SOFT_DATA6 to the memory controller 200 of FIG. 4.

Therefore, the number of data provided from the memory device 100 of FIG. 4 to the memory controller 200 of FIG. 4 is reduced, and the memory device 100 of FIG. 4 performs the logical operation for the second error correction instead of the memory controller 200 of FIG. 4. Thus, the error correction efficiency of the memory controller 200 of FIG. 4 may be increased.

In an embodiment of the present disclosure, the memory device 100 of FIG. 4 may generate the new soft bit based on the seventy-first and seventy-third soft bits SOFT_BIT71 and SOFT_BIT73. When the memory device 100 of FIG. 4 generates the new soft bit, the number of data provided to the memory controller 200 of FIG. 4 may be further reduced.

Specifically, referring to FIGS. 15A and 15B, the memory device 100 of FIG. 4 may perform the XNOR operation on the seventy-first and seventy-third soft bits SOFT_BIT71 and SOFT_BIT73 to generate a seventy-fourth soft bit SOFT_BIT74.

For example, since the seventy-first and seventy-third soft bits SOFT_BIT71 and SOFT_BIT73 of the memory cells of the A1 and A8 regions are “1”, the data obtained by performing the XNOR operation on the seventy-first and seventy-third soft bits SOFT_BIT71 and SOFT_BIT73 may be “1”.

In an embodiment of the present disclosure, since the seventy-first soft bit SOFT_BIT71 of the memory cells of the A2, A3, A6, and A7 regions is “1”, and the seventy-third soft bit SOFT_BIT73 of the memory cells of the A2, A3, A6, and A7 regions is “0”, the data obtained by performing the XNOR operation on the seventy-first and seventy-third soft bits SOFT_BIT71 and SOFT_BIT73 may be “0”.

In an embodiment of the present disclosure, since the seventy-first and seventy-third soft bits SOFT_BIT71 and SOFT_BIT73 of the memory cells of the A4 and A5 regions are “0”, the data obtained by performing the XNOR operation on the seventy-first and seventy-third soft bits SOFT_BIT71 and SOFT_BIT73 may be “1”.

As a result, the memory device 100 of FIG. 4 may provide only the seventy-fourth and seventy-second soft bits SOFT_BIT74 and SOFT_BIT72 to the memory controller 200 of FIG. 4 instead of providing all of the seventy-first to seventy-third soft bits SOFT_BIT71 to SOFT_BIT73 to the memory controller 200 of FIG. 4. Therefore, through the additional XNOR operation of the memory device 100 of FIG. 4, the number of data provided to the memory controller 200 of FIG. 4 may be further reduced, and the error correction efficiency of the memory controller 200 of FIG. 4 may be further increased.

Although not shown in the present drawings, the memory device 100 of FIG. 4 may provide only data obtained by performing the XNOR operation on the seventy-fourth and seventy-second soft bits SOFT_BIT74 and SOFT_BIT72 to the memory controller 200 of FIG. 4. That is, the memory device 100 of FIG. 4 may provide smaller number of data to the memory controller 200 of FIG. 4 instead of providing the seventy-fourth and seventy-second soft bits SOFT_BIT74 and SOFT_BIT72 to the memory controller 200 of FIG. 4. In this case, through the additional XNOR operation of the memory device 100 of FIG. 4, the number of data provided to the memory controller 200 of FIG. 4 may be further reduced, and the error correction efficiency of the memory controller 200 of FIG. 4 may be further increased.

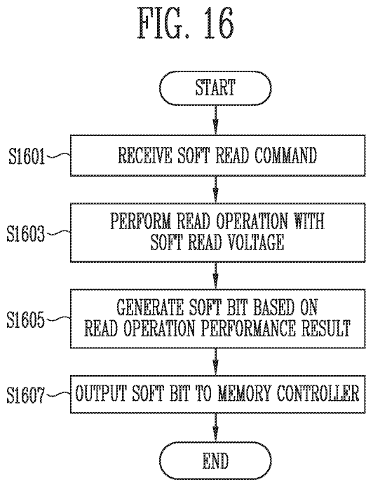

FIG. 16 is a diagram illustrating the operation of the memory device in accordance with some embodiments of the present disclosure.

Referring to FIG. 16, in step S1601, the memory device may receive the soft read command from the memory controller. The soft read command may be output from the memory controller after the first error correction operation is failed. That is, the soft read command may be the command for the second error correction when the first error correction of the read data provided from the memory device is failed. In addition, the soft read command may be the command for instructing to perform the read operation with the voltages higher and lower than the read voltage used when performing the failed read operation.

Therefore, when the memory device receives the soft read command from the memory controller, the read operation may be performed with the soft read voltage including voltages higher and lower than the read voltage used when performing the failed read operation (S1603).

In accordance with some embodiments of the present disclosure, when the memory device performs the read operation corresponding to the soft read command, the memory device may generate the soft bit based on the data obtained from the read operation (S1605). The soft bit may be data obtained by performing the XNOR operation on the read data according to the soft read command.

For example, when the soft data is read by the read operation corresponding to the soft read command, the memory device may generate the soft bit by performing the XNOR operation on the soft data. The generated soft bit may be provided to the memory controller (S1607).

Therefore, the memory device according to some embodiments of the present disclosure may provide only the soft data to the memory controller without providing all soft data obtained based on the soft read command to the memory controller, thereby reducing the number of data provided to the memory controller. As a result, since the memory device performs the logical operation for the second error correction in advance instead of the memory controller, the error correction efficiency of the memory controller may be increased.

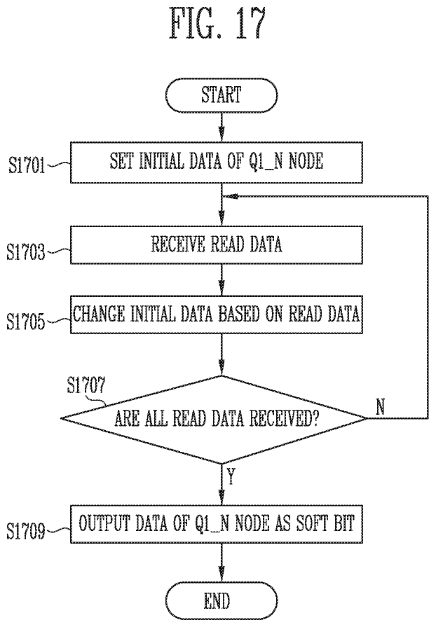

FIG. 17 is a diagram illustrating the operation of the memory device in accordance with some embodiments of the present disclosure.

Referring to FIG. 17, steps S1701 to S1709 show generating the soft bit.

In step S1701, the initial data of the Q1_N node of the page buffers included in the page buffer group of the memory device may be set. The Q1_N node is one of the nodes connected to the latch, and the initial data may be “1”. When the initial data of the Q1_N node is set, the page buffer may read the data stored in the memory cell array and receive the read data (S1703).

In an embodiment of the present disclosure, when the page buffer receives the read data, the read data may be inverted and provided to the SO node. That is, when the read data is “1”, “0” may be set in the SO node, and when the read data is “0”, “1” may be set in the SO node. The page buffer may change the initial data based on the read data (S1705).

Specifically, when the initial data is “1” and “0” is set in the SO node, the initial data may maintain “1” without change. When the initial data is “1” and “1” is set in the SO node, the initial data may be changed from “1” to “0”. Thereafter, whenever the page buffer receives data, it may be determined whether or not the data of the Q1_N node is changed, based on the data provided to the SO node.

When the initial data of the Q1_N node of the page buffer is changed, the memory device may determine whether all read data according to the soft read command are received (S1707).

When all read data corresponding to the soft read command are received (Y), the memory device may output the data of the Q1_N node that is finally changed as the soft bit (S1709). That is, the data of the Q1_N node may be the soft bit.

However, when all read data corresponding to the soft read command is not received (N), the process may proceed to step S1703 again, and the page buffer may receive the read data obtained by reading the data stored in the memory cell array.

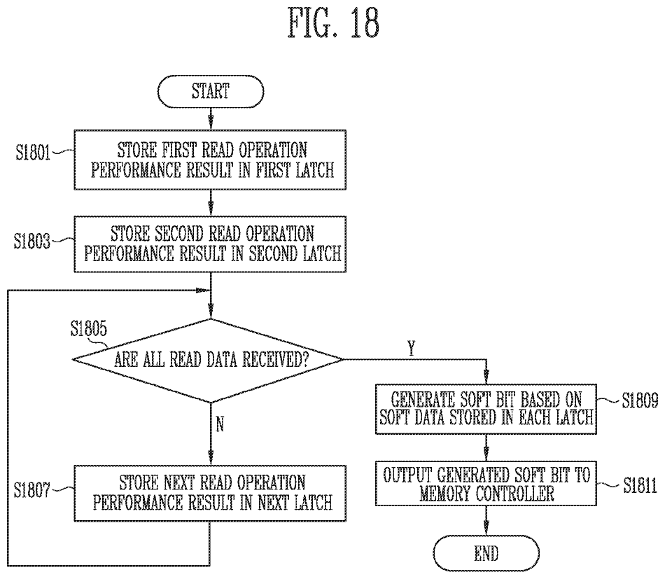

FIG. 18 is a diagram illustrating the operation of the memory device in accordance with some embodiments of the present disclosure.

Referring to FIGS. 17 and 18, steps S1801 to S1811 show the method of generating the soft bit, which are different from those of FIG. 17.

In step S1801, the memory device may store data obtained from the first read operation into the first latch. The first read operation may be one of the operations corresponding to the soft read command received from the memory controller. That is, the first read operation may be performed with the read voltage different from the read voltage used when performing the failed read operation.

In step S1803, the memory device may store data obtained from the second read operation into the second latch. The second read operation may be one of the operations corresponding to the soft read command received from the memory controller. In addition, the second read operation may be the read operation performed with another read voltage, but not the read voltage of the first read operation and the read voltage used when performing the failed read operation.

When the read data corresponding to the soft read command is stored into each latch through steps S1801 and S1803, the memory device may determine whether all read operations corresponding to the soft read command are performed (S1805).

When all read operations corresponding to the soft read command are not performed (N), the memory device may store data obtained from the next read operation into the next latch.

However, when all read operations corresponding to the soft read command are performed (Y), the memory device may provide only the soft bit to the memory controller.

In an embodiment of the present disclosure, when all read operations corresponding to the soft read command are performed, the memory device may generate the soft bit by performing an XNOR operation on the soft data stored in each latch (S1809). The XNOR operation performed by the memory device may be performed at least once depending from the number of latches in which data is stored.

When the soft bit is generated, the memory device may provide the generated soft bit to the memory controller (S18011). Therefore, since the memory device provides only the soft bit to the memory controller, the number of data provided from the memory device to the memory controller may be reduced.

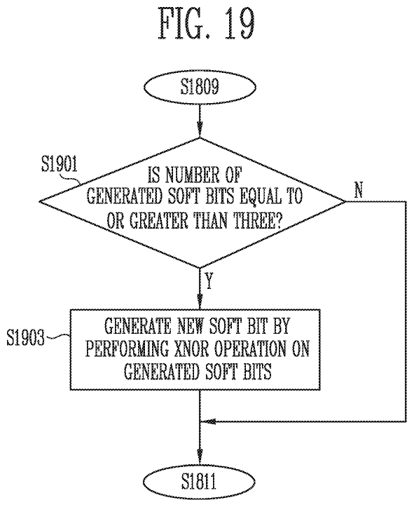

FIG. 19 is a diagram illustrating the operation of the memory device in accordance with some embodiments of the present disclosure.

Referring to FIGS. 18 and 19, FIG. 19 shows the operation of the memory device performed between steps S1809 and S1811.

In an embodiment, the memory device may perform the XNOR operation at least once depending from the number of latches in which data is stored.

Specifically, the memory device may determine whether three or more soft bits are generated based on the soft data corresponding to the soft read command (S1901). That is, when two or less soft bits are generated, the memory device may provide the generated bits to the memory controller. However, when three or more soft bits are generated, the memory device may logically operate some of the generated soft bits.

In an embodiment of the present disclosure, when the number of soft bits generated based on the soft data corresponding to the soft read command is not equal to or greater than three (N), that is, when the number of soft bits is equal to or less than two, the process may proceed to step S1811, and the memory device may provide one or two soft bits to the memory controller.

However, when three or more soft bits are generated based on the soft data corresponding to the soft read command (Y), the memory device may generate a new soft bit by performing an XNOR operation on the generated soft bits. (S1903). That is, in order to further reduce the number of data being provided to the memory controller, the memory device may perform the XNOR operation on the generated soft bits. In addition, the memory device may provide the newly generated soft bit and the soft bit on which the XNOR operation is not performed, to the memory controller.

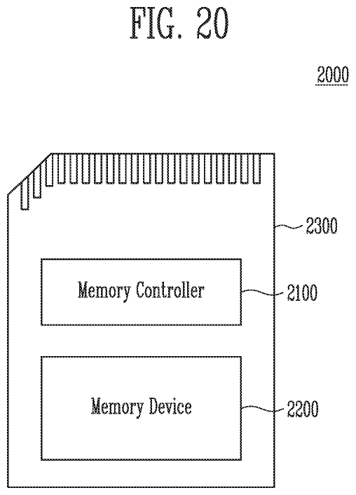

FIG. 20 is a block diagram illustrating a memory card system including the storage device in accordance with some embodiments of the present disclosure.

Referring to FIG. 20, the memory card system 2000 includes a memory controller 2100, a memory device 2200, and a connector 2300.

The memory controller 2100 is connected to the memory device 2200. The memory controller 2100 is configured to access the memory device 2200. For example, the memory controller 2100 is configured to control read, write, erase, and background operations of the memory device 2200. The memory controller 2100 is configured to provide an interface between the memory device 2200 and the host Host. The memory controller 2100 is configured to drive firmware for controlling the memory device 2200. The memory device 2200 may be implemented equally to the memory device 100 of FIG. 2 described with reference to FIG. 2.

In an embodiment of the present disclosure, when a read operation performed by the memory device 2200 is failed, the memory device 2200 may receive a soft read command from the memory controller 2100 to perform a read operation corresponding to the soft read command. At this time, the memory device 2200 may not provide all read data obtained from the read operation corresponding to the soft read command to the memory controller 2100, but the read data obtained by performing an XNOR operation on the read data to the memory controller 2100.

As a result, the number of data provided from the memory device 2200 to the memory controller 2100 may be reduced. In addition, since the memory controller 2100 performs the XNOR operation on the read data for the second error correction, error correction efficiency of the memory controller 2100 may increase.

As an example, the memory controller 2100 may include components such as a random access memory (RAM), a processor, a host interface, a memory interface, and an error corrector.

The memory controller 2100 may communicate with an external device through the connector 2300. The memory controller 2100 may communicate with an external device (for example, the host) according to a specific communication standard. As an example, the memory controller 2100 is configured to communicate with an external device through at least one of various communication standards such as a universal serial bus (USB), a multi-media card (MMC), an embedded MMC (MCM), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, a universal flash storage (UFS), Wi-Fi, Bluetooth, and an NVMe. As an example, the connector 2300 may be defined by at least one of the various communication standards described above.

As an example, the memory device 2200 may be implemented as various non-volatile memory elements such as an electrically erasable and programmable ROM (EEPROM), a NAND flash memory, a NOR flash memory, a phase-change RAM (PRAM), a resistive RAM (ReRAM), a ferroelectric RAM (FRAM), and a spin-torque magnetic RAM (STT-MRAM).

The memory controller 2100 and the memory device 2200 may be integrated into one semiconductor device to configure a memory card. For example, the memory controller 2100 and the memory device 2200 may be integrated into one semiconductor device to configure a memory card such as a PC card (personal computer memory card international association (PCMCIA)), a compact flash card (CF), a smart media card (SM or SMC), a memory stick, a multimedia card (MMC, RS-MMC, MMCmicro, or eMMC), an SD card (SD, miniSD, microSD, or SDHC), and a universal flash storage (UFS).

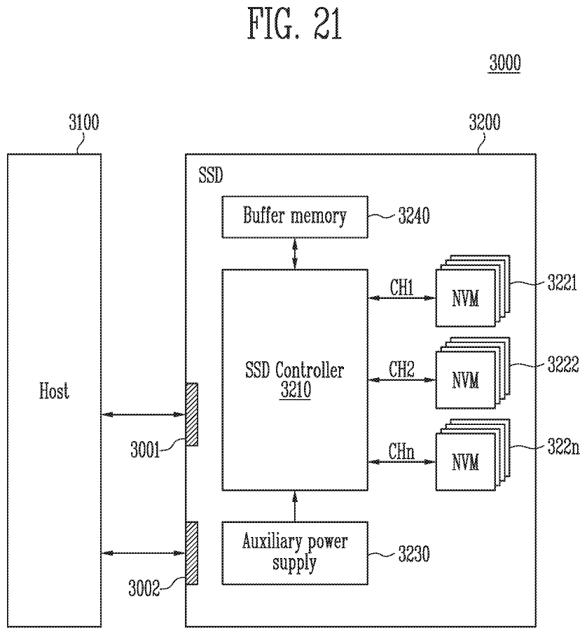

FIG. 21 is a block diagram illustrating a solid state drive (SSD) system including the storage device in accordance with some embodiments of the present disclosure.

Referring to FIG. 21, the SSD system 3000 includes a host 3100 and an SSD 3200. The SSD 3200 exchanges a signal SIG with the host 3100 through a signal connector 3001 and receives power PWR through a power connector 3002. The SSD 3200 includes an SSD controller 3210, a plurality of flash memories 3221 to 322n, an auxiliary power device 3230, and a buffer memory 3240.

In an embodiment of the present disclosure, the SSD controller 3210 may perform the function of the memory controller 200 of FIG. 1 described with reference to FIG. 1.

The SSD controller 3210 may control the plurality of flash memories 3221 to 322n in response to the signal SIG received from the host 3100. As an example, the signal SIG may be signals based on an interface between the host 3100 and the SSD 3200. For example, the signal SIG may be a signal defined by at least one of interfaces such as a universal serial bus (USB), a multi-media card (MMC), an embedded MMC (MCM), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, a universal flash storage (UFS), Wi-Fi, Bluetooth, and an NVMe.

In an embodiment of the present disclosure, when a first error correction for data obtained from a read operation performed by the plurality of flash memories 3221 to 322n is failed, the plurality of flash memories 3221 to 322n may receive a soft read command from the SSD controller 3210 to perform a read operation corresponding to the soft read command. At this time, the plurality of flash memories 3221 to 322n may not provide all read data obtained from the read operation corresponding to the soft read command to the SSD controller 3210, but may provide the read data to the SSD controller 3210 by performing an XNOR operation on the read data.

As a result, the number of data provided from the plurality of flash memories 3221 to 322n to the SSD controller 3210 may be reduced. In addition, since the plurality of flash memories 3221 to 322n perform the XNOR operation on the read data, error correction efficiency of the SSD controller 3210 may increase.

The auxiliary power device 3230 is connected to the host 3100 through the power connector 3002. The auxiliary power device 3230 may receive the power PWR from the host 3100 and may charge the power. The auxiliary power device 3230 may provide power of the SSD 3200 when power supply from the host 3100 is not smooth. As an example, the auxiliary power device 3230 may be positioned in the SSD 3200 or may be positioned outside the SSD 3200. For example, the auxiliary power device 3230 may be positioned on a main board and may provide auxiliary power to the SSD 3200.

The buffer memory 3240 operates as a buffer memory of the SSD 3200. For example, the buffer memory 3240 may temporarily store data received from the host 3100 or data received from the plurality of flash memories 3221 to 322n, or may temporarily store metadata (for example, a mapping table) of the flash memories 3221 to 322n. The buffer memory 3240 may include a volatile memory such as a DRAM, an SDRAM, a DDR SDRAM, an LPDDR SDRAM, and a GRAM, or a non-volatile memory such as an FRAM, a ReRAM, an STT-MRAM, and a PRAM.

What is claimed is:

1. A memory device comprising a memory cell array and a page buffer connected to the memory cell array through a bit line, wherein the page buffer comprises:
a plurality of latches; and
a read data operating component configured to generate a soft bit by operating soft data, which are data read from the memory cell array, and to provide the soft bit to a memory controller, in a second read operation performed when a first read operation has failed.

2. The memory device of claim 1, wherein the second read operation is performed with at least one read voltage lower than a read voltage used in the first read operation, and at least one read voltage higher than the read voltage of the first read operation.

3. The memory device of claim 1, wherein, when the second read operation is performed, the soft data are stored into any one of the plurality of latches.

4. The memory device of claim 3, wherein, when all operations corresponding to the second read operation are performed, the read data operating component receives the soft data from the plurality of latches.

5. The memory device of claim 1, wherein the read data operating component generates the soft bit by performing an exclusive-NOR operation on the soft data.

6. The memory device of claim 1, wherein the read data operating component determines whether to perform the logical operation on the soft bit based on the number of the soft bits.

7. A method of operating a memory device comprising a memory cell array and a page buffer connected to the memory cell array through a bit line, the method comprising:
performing a first read operation;
changing a read voltage to perform a second read operation when the first read operation has failed;
logically operating soft data which are data read from the memory cell array in the second read operation to generate at least one soft bit; and
providing the at least one soft bit to a memory controller.

8. The method of claim 7, wherein the second read operation is performed with at least one read voltage lower than a read voltage of the first read operation, and at least one read voltage higher than the read voltage of the first read operation.

9. The method of claim 7, wherein, in performing the second read operation, each of the soft data is stored into any one of a plurality of latches included in the memory device, and
in logically operating the soft data, when all operations corresponding to the second read operation are performed, the soft data are received from the plurality of latches to perform an exclusive-NOR operation.

10. The method of claim 8, wherein, in generating the at least one soft bit, when the second read operation is performed with two read voltages lower than the read voltage of the first read operation, and two read voltages higher than the read voltage of the first read operation, two soft bits are generated by logically operating the soft data.

11. The method of claim 10, wherein, in providing the at least one soft bit to the memory controller, the two soft bits are provided without logical operation on the two soft bits.

12. The method of claim 10, wherein, in providing the at least one soft bit to the memory controller, only data obtained by logically operating the two soft bits is provided.

13. The method of claim 8, wherein, in generating the at least one soft bit, when the second read operation is performed with three read voltages lower than the read voltage of the first read operation, and three read voltages higher than the read voltage of the first read operation, three soft bits are generated by logically operating the soft data.

14. The method of claim 13, wherein, in providing the at least one soft bit to the memory controller, operating data obtained by logically operating two soft bits among the three soft bits and remaining soft bit except the two soft bits are provided.

15. The method of claim 13, wherein, in providing the at least one soft bit to the memory controller, after operated data has been generated by logically operating two soft bits among the three soft bits, one data obtained by logically operating the operated data and remaining soft bit except two soft bits is provided.

16. The method of claim 8, wherein, in generating the at least one soft bit, when the second read operation is performed with four read voltages lower than the read voltage of the first read operation, and four read voltages higher than the read voltage of the first read operation, four soft bits are generated by logically operating the soft data.

17. The method of claim 16, wherein, in providing the at least one soft bit to the memory controller, two data generated by logically operating two soft bits among the four soft bits are provided.

18. The method of claim 16, wherein, in providing the at least one soft bit to the memory controller, two data are generated by logically operating two soft bits among the four soft bits, and only one data obtained by logically operating the generated two data is provided.

19. A memory device comprising a memory cell array and a page buffer connected to the memory cell array through a bit line, wherein the page buffer comprises:
a plurality of latches; and
a plurality of transistors, and
wherein the page buffer outputs a soft bit generated by logically operating data provided to a second node connected to a latch included in the page buffer among the plurality of latches, according to data provided to a first node connected to the bit line.

20. The memory device of claim 19, wherein the page buffer sets default data of the second node, and maintains the data of the second node as the default data or changes the data of the second node according to the data read to the first node.
